(19) United States
(12) Patent Application Publication
(10) Pub. No.: US 2023/0067270 A1
(43) Pub. Date: Mar. 2, 2023

(54) MEMORY DEVICE INCLUDING DIELECTRIC STRUCTURES HAVING REPEATING PATTERNS

(71) Applicants: Dheeraj Kumar, Boise, ID (US); Sumeet C. Pandey, Boise, ID (US); Surendranath C. Eruvuru, Boise, ID (US)

(72) Inventors: Dheeraj Kumar, Boise, ID (US); Sumeet C. Pandey, Boise, ID (US); Surendranath C. Eruvuru, Boise, ID (US)

(21) Appl. No.: 17/885,018

(22) Filed: Aug. 10, 2022

Related U.S. Application Data
(60) Provisional application No. 63/239,351, filed on Aug. 31, 2021.

(51) Int. Cl. H01L 27/11565; H01L 27/11519; H01L 27/11556; H01L 27/11582

(52) U.S. Cl. CPC H01L 27/11565; H01L 27/11519; H01L 27/11556; H01L 27/11582

(57) ABSTRACT

Some embodiments include apparatuses and methods of forming the apparatuses. One of the apparatuses includes first tiers located one over another, the first tiers including respective first memory cells and first control gates for the memory cells, the first memory cells located along respective first pillars, the first pillars extending through the first tiers; second tiers located one over another, the second tiers including respective second memory cells and second control gates for the memory cells, the second memory cells located along respective second pillars, the second pillars extending through the second tiers; and a dielectric structure formed in a slit between the first tiers and the second tiers, the dielectric structure including an edge along a length of the slit and adjacent the first tiers, wherein the edge has a repeating pattern of a shape.

### PRIORITY APPLICATION

This application claims the benefit of priority to U.S. Provisional Application Ser. No. 63/239,351, filed Aug. 31, 2021, which is incorporated herein by reference in its entirety.

### FIELD

Embodiments described herein relate to memory devices including dielectric structures between adjacent memory blocks and support structures at staircase regions of the memory device.

### BACKGROUND

Dimensions of structures of components in a memory device (e.g., a flash memory device) are relatively small (e.g., in nanometer size). At a certain dimension, collapse in some structures of the memory device may occur during fabrication of the memory device. Some conventional techniques use additional chemical process steps to prevent such collapse. However, the additional steps can increase the cost of fabricating the memory device.

### BRIEF DESCRIPTION OF THE DRAWINGS

FIG. 1 shows an apparatus in the form of a memory device, according to some embodiments described herein.

FIG. 2 shows a schematic of an apparatus in the form a memory device having a memory cell array and memory cell blocks, according to some embodiments described herein.

FIG. 3A shows a top view of a structure of the memory device of FIG. 2 including the memory cell array, staircase regions, and dielectric structures between the memory cell blocks, according to some embodiments described herein.

FIG. 3B shows a portion (e.g., a side view) of the memory device of FIG. 3A.

FIG. 4 through FIG. 7 show memory devices including support structure having different shapes, according to some embodiments described herein.

FIG. 8A through FIG. 8E show reticles including regions having a non-circular shape, according to some embodiments described herein.

FIG. 9A, FIG. 10A, and FIG. 11A show memory devices including slits and dielectric structures having repeating patterns of shapes, according to some embodiments described herein.

FIG. 9B, FIG. 10B, and FIG. 11B show reticles including edges having repeating patterns of shapes, according to some embodiments described herein.

FIG. 12A through FIG. 16C show different views of structures during processes of forming the memory device of FIG. 2 through FIG. 3B, according to some embodiments described herein.

FIG. 17 shows a system including lithograph equipment including a reticle, according to some embodiments described herein.

### DETAILED DESCRIPTION

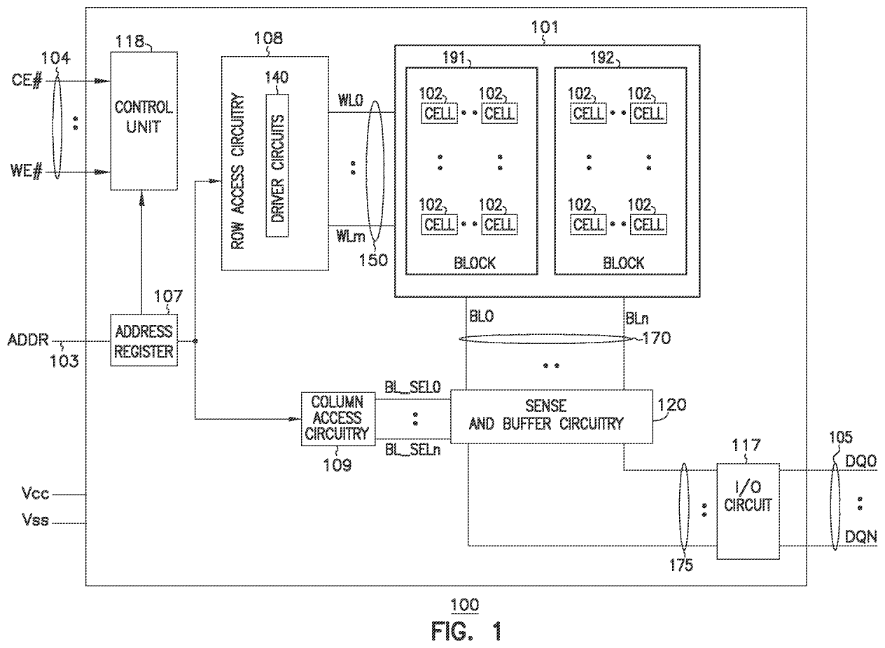

The techniques described herein involve a memory device having, among other structures, dielectric structures between adjacent memory blocks to electrically separate one memory block from another, staircase structures in the memory blocks, and support structures in the memory device. The dielectric structures can include edges having a repeating pattern of a shape. The shape can include a zigzag shape or other shapes. The support structures include respective pillars having length extending vertically through multiple levels of materials of the memory device. The boundary (e.g., perimeter) of a cross-section (perpendicular to the length) of the pillar has a non-circular shape (not a shape of a circle). Examples for the shape of the support structures include bullet, polygon (e.g., square, rectangular, T-shape, barn shape), elliptical, and other non-circular shapes. The memory device described herein can include any combination of dielectric structures having a repeating pattern of a shape and support structures having a non-circular shape. The techniques described herein also involve reticles that can be used during part of forming the described memory device. Providing the repeating patterns and shapes described herein can mitigate or prevent collapse of some structures of the memory device during the process of forming the memory device. Improvements and benefits of the techniques described herein are further discussed below with reference to FIG. 1 through FIG. 17.

FIG. 1 shows an apparatus in the form of a memory device 100, according to some embodiments described herein. Memory device 100 can include a memory array (or multiple memory arrays) 101 containing memory cells 102 arranged in blocks (blocks of memory cells), such as blocks 191 and 192. In the physical structure of memory device 100, memory cells 102 can be arranged vertically (e.g., stacked one over another) over a substrate (e.g., a semiconductor substrate) of memory device 100. FIG. 1 shows memory device 100 having two blocks 191 and 192 as an example. Memory device 100 can have more than two blocks.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks 191 and 192 and data lines 170 to selectively exchange information (e.g., data) with memory cells 102.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks 191 and 192 are to be accessed during a memory operation. Memory device 100 can include drivers (driver circuits) 140, which can be part of row access circuitry 108. Drivers 140 can operate (e.g., operate as switches) to form (or not to form) conductive paths (e.g., current paths) between nodes providing voltages and respective access lines 150 during operations of memory device 100.

Memory device 100 can perform a read operation to read (e.g., sense) information (e.g., previously stored information) from memory cells 102 of blocks 191 and 192, or a write (e.g., programming) operation to store (e.g., program) information in memory cells 102 of blocks 191 and 192. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks 191 and 192.

Memory device 100 can include a control unit 118 that can be configured to control memory operations of memory device 100 based on control signals on lines 104. Examples of the control signals on lines 104 include one or more clock signals and other signals (e.g., a chip-enable signal CE#, a write-enable signal WE#) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that may cause memory device 100 to perform a corresponding memory operation (e.g., e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks 191 and 192 and provide the value of the information to lines (e.g., global data lines) 175. Sense and buffer circuitry 120 can also be configured to use signals on lines 175 to determine the value of information to be stored (e.g., programmed) in memory cells 102 of blocks 190 and 191 (e.g., during a write operation) based on the values (e.g., voltage values) of signals on lines 175 (e.g., during a write operation).

Memory device 100 can include input/output (I/O) circuitry 117 to exchange information between memory cells 102 of blocks 191 and 192 and lines (e.g., I/O lines) 105. Signals DQO through DQN on lines 105 can represent information read from or stored in memory cells 102 of blocks 191 and 192. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits. A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3-dimensional (3-D) NAND) or a NOR flash memory device, or another kind of memory device, such as a variable resistance memory device (e.g., a phase change memory device or a resistive Random Access Memory (RAM) device.

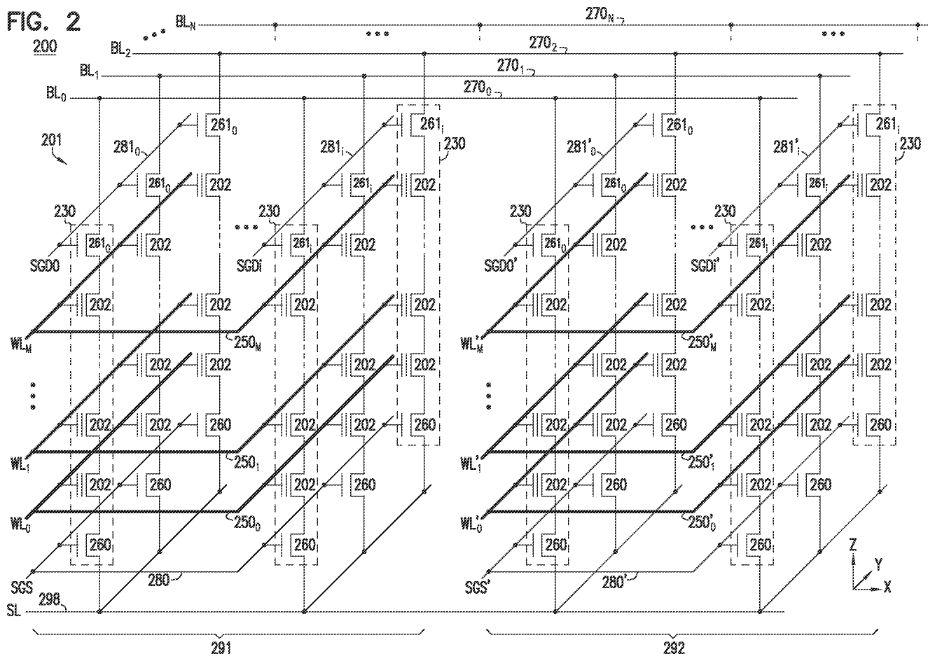

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 17.

FIG. 2 shows a schematic of an apparatus in the form a memory device 200 having a memory cell array 201 and blocks (e.g., memory cell blocks) 291 and 292, according to some embodiments described herein. Memory device 200 can include a non-volatile (e.g., NAND flash memory device) or other types of memory devices. Memory device 200 can correspond to memory device 100. For example, memory array (or multiple memory arrays) 201 and blocks 291 and 292 can correspond to memory array 101 and blocks 191 and 192, respectively, of memory device 100 of FIG. 1.

As shown in FIG. 2, memory device 200 can include memory cells 202, data lines 270₀ through 270_{N} (270₀-270_{N}), control gates 250₀ through 250_{M} in block 291, and control gates 250′₀ through 250′_{M} in block 292. Data lines 270₀-270_{N} can correspond to part of data lines 170 of memory device 100 of FIG. 1. In FIG. 2, label “N” (index N) next to a number (e.g., 270_{N}) represents the number of data lines of memory device 200. For example, if memory device 200 includes 16 data lines, then N is 15 (data lines 270₀ through 270₁₅). In FIG. 2, label “M” (index M) next to a number (e.g., 250_{M}) represents the number of control gates memory device 200. For example, if memory device 200 includes 128 control gates, then M is 127 (control gates 250o through 250₁₂₇). Memory device 200 can have the same number of control gates (e.g., M−1 control gates) among the blocks (e.g., blocks 291 and 292) of memory device 200.

In FIG. 2, data lines 270₀-270_{N} can include (or can be part of) bit lines (e.g., local bit lines) of memory device 200. As shown in FIG. 2, data lines 270₀-270_{N} can carry signals (e.g., bit line signals) BL₀ through BL_{N}, respectively. In the physical structure of memory device 200, data lines 270₀-270_{N} can be structured as conductive lines and have respective lengths extending in the Y-direction.

As shown in FIG. 2, memory cells 202 can be organized into separates blocks (memory blocks or blocks of memory cells) such as blocks 291 and 292. FIG. 2 shows memory device 200 including two blocks 291 and 292 as an example. However, memory device 200 can include numerous blocks. The blocks (e.g., blocks 291 and 292) of memory device 200 can share data lines (e.g., data lines 270₀-270_{N}) to carry information (in the form of signals) read from or to be stored in memory cells of selected memory cells (e.g., selected memory cells in block 291 or 292) of memory device 200.

Control gates 250₀-250_{M} can be part of local word lines, which can be part of (or can be coupled to) access lines (e.g., global word lines) of memory device 200 that can correspond to access lines 150 of memory device 100 of FIG. 1. Control gates 250′₀-250′_{M} can be another part of other local word lines, which can be part of access lines (e.g., global word lines) of memory device 200. Control gates 250₀-250_{M} can be electrically separated from control gates 250′₀-250′_{M}. Thus, blocks 291 and 292 can be accessed separately (e.g., accessed one at a time). For example, block 291 can be accessed at one time using control gates 250₀-250_{M}, and block 292 can be accessed at another time using control gates 250′₀-250′_{M} at another time.

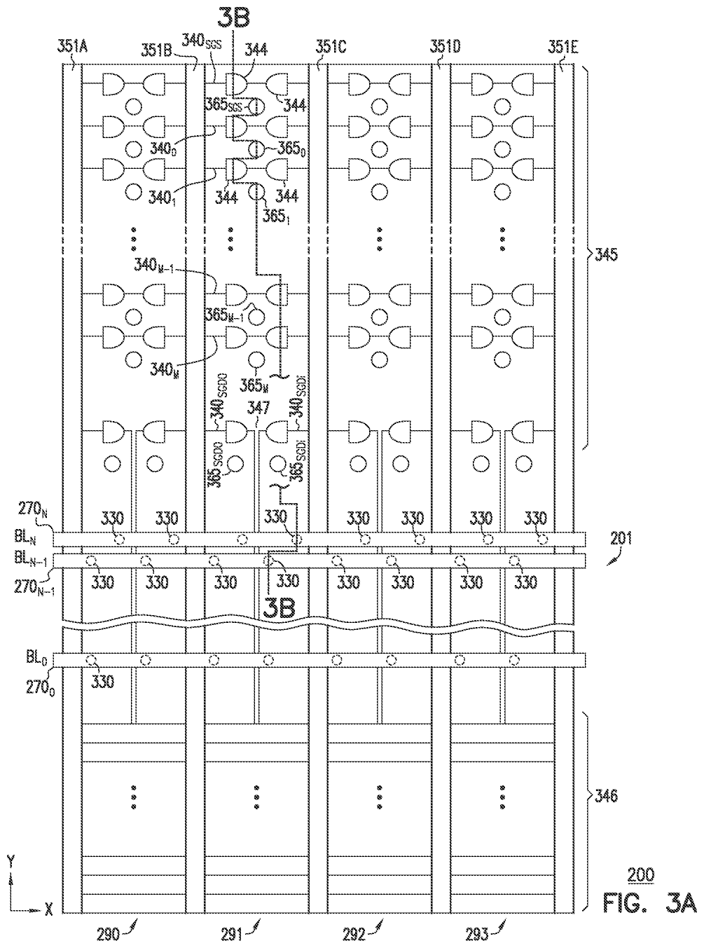

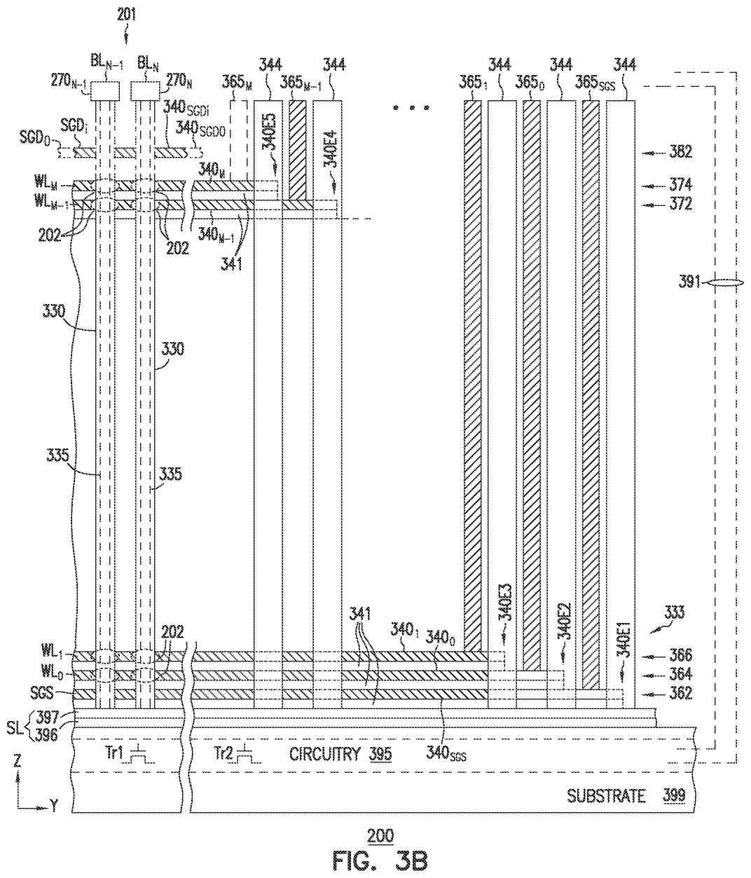

FIG. 2 shows directions X, Y, and Z that can be relative to the physical directions (e.g., dimensions) of the structure of memory device 200. For example, the Z-direction can be a direction perpendicular to (e.g., vertical direction with respect to) a substrate of memory device 200 (e.g., a substrate 399 shown in FIG. 3B). The Z-direction is perpendicular to the X-direction and Y-direction (e.g., the Z-direction is perpendicular to an X-Y plan of memory device 200). In the physical structure of memory device 200, control gates 250₀-250_{M} can be formed on different levels (e.g., layers) of memory device 200 in the Z-direction. In this example, the levels (e.g., layers) of control gates 250₀-250_{M} can be formed (e.g., stacked) one level (one layer of material) over another in the Z-direction.

As shown in FIG. 2, memory cells 202 can be included in respective memory cell strings 230 in each of the blocks (e.g., blocks 291 and 292) of memory device 200. Each of memory cell strings 230 can have series-connected memory cells (e.g., M+1 series-connected memory cells) in the Z-direction. In a physical structure of memory device 200, memory cells 202 in each of memory cell strings 230 can be formed (e.g., stacked vertically one over another) in different levels (e.g., M−1 different layers in the example of FIG. 2) in the Z-direction of memory device 200. The number of memory cells in each of strings 230 can be equal to the number of levels (e.g., layers) of control gates (e.g., control gates 250₀-250_{M}) of memory device 200.

As shown in FIG. 2, control gates 2500-250M can carry corresponding signals WL₀-WL_{M}. As mentioned above, control gates 250₀-250_{M} can include (or can be parts of) access lines (e.g., word lines) of memory device 200. Each of control gates 250₀-250_{M} can be part of a structure (e.g., a level) of a conductive material (e.g., a layer of conductive material) located in a level of memory device 200. Memory device 200 can use signals WL₀-WL_{M} to selectively control access to memory cells 202 of block 291 during an operation (e.g., read, write, or erase operation). For example, during a read operation, memory device 200 can use signals WL₀-WL_{M} to control access to memory cells 202 of block 291 to read (e.g., sense) information (e.g., previously stored information) from memory cells 202 of block 291. In another example, during a write operation, memory device 200 can use signals WL₀-WL_{M} to control access to memory cells 202 of block 291 to store information in memory cells 202 of block 291.

As shown in FIG. 2, control gates 250′₀-250′_{M} can carry corresponding signals WL′₀-WL′_{M}. Each of control gates 250′₀-250′_{M} can be part of a structure (e.g., a level) of a conductive material (e.g., a layer of conductive material) located in a single-level of memory device 200. Control gates 250′₀-250′_{M} can be located in the same levels (in the Z-direction) as control gates 250₀-250_{M}, respectively. As mentioned above, control gates 250′₀-250′_{M} (e.g., local word lines) can be electrically separated from control gates 250₀-250_{M} (e.g., other local word lines)

Memory device 200 can use signals WL′₀-WL′_{M} to control access to memory cells 202 respectively, of block 292 during an operation (e.g., read, write, or erase operation). For example, during a read operation, memory device 200 can use signals WL′₀-WL′_{M} to control access to memory cells 202 of block 292 to read (e.g., sense) information (e.g., previously stored information) from memory cells 202 of block 292. In another example, during a write operation, memory device 200 can use signals WL′₀-WL′_{M} to control access to memory cells 202 of block 292 to store information in memory cells 202 block 292.

As shown in FIG. 2, memory cells in different memory cell strings in the same a block can share (e.g., can be controlled by) the same control gate in that block. For example, in block 291, memory cells 202 coupled to control gate 250₀ can share (can be controlled by) control gate 250₀. In another example, memory cells 202 coupled to control gate 250₁ can share (can be controlled by) control gate 250₁. In another example, in block 292, memory cells 202 coupled to control gate 250′₀ can share (can be controlled by) control gate 250′₀. In another example, memory cells 202 coupled to control gate 250′₁can share (can be controlled by) control gate 250′₁.

Memory device 200 can include a source (e.g., a source line, a source plate, or a source region) 298 that can carry a signal (e.g., a source line signal) SL. Source 298 can be structured as a conductive line or a conductive plate (e.g., conductive region) of memory device 200. Source 298 can be common source line (e.g., common source plate or common source region) of block 291 and 292. Source 298 can be coupled to a ground connection of memory device 200.

Memory device 200 can include select transistors (e.g., drain select transistors) 261₀ through 261ᵢ (261₀-261ᵢ) and select gates (e.g., drain select gates) 281₀ through 281ᵢ. Transistors 261₀ can share the same select gate 281₀. Transistors 261ᵢ can share the same select gate 281ᵢ. Select gates 281₀-281ᵢ can carry signals SGD₀ through SGDᵢ, respectively.

Transistors 261₀-261ᵢ can be controlled (e.g., turned on or turned off) by signals SGD₀-SGDᵢ, respectively. During a memory operation (e.g., a read or write operation) of memory device 200, transistors 261₀-261ᵢ can be turned on (e.g., by activating respective signals SGD₀-SGDᵢ) to couple memory cell strings 230 of block 291 to respective data lines 270₀-270_{N}. Transistors 261₀-261ᵢ can be turned off (e.g., by deactivating respective signals SGD₀-SGDᵢ) to decouple the memory cell strings 230 of block 291 from respective data lines 270₀-270_{N}.

Memory device 200 can include transistors (e.g., source select transistors) 260, each of which can be coupled between source 298 and memory cells 202 in a respective memory cell string (one of memory cell strings 230) of block 291. Memory device 200 can include a select gate (e.g., source select gate) 280. Transistors 260 can share select gate 280. Transistors 260 can be controlled (e.g., turned on or turned off) by the same signal, such as SGS signal (e.g., source select gate signal) provided on select gate 280. During a memory operation (e.g., a read or write operation) of memory device 200, transistors 260 can be turned on (e.g., by activating an SGS signal) to couple the memory cell strings of block 291 to source 298. Transistors 260 can be turned off (e.g., by deactivating the SGS signal) to decouple the memory cell strings of block 291 from source 298.

Memory device 200 can include similar select gates and select transistors in block 292. For example, in block 292, memory device 200 can include select gates (e.g., drain select gates) 281′₀ through 281′ᵢ, and transistors (e.g., drain select transistors) 261₀-261ᵢ. Transistors 261₀ of block 292 can share the same select gate 281′₀. Transistors 261ᵢ of block 292 can share the same select gate 281′ᵢ. Select gates 281′₀ through 281′ᵢ can carry signals SGD0′ through SGDi′, respectively.

Transistors 261₀-261ᵢ of block 292 can be controlled (e.g., turned on or turned off) by signals SGD0′ through SGDi′, respectively. During a memory operation (e.g., a read or write operation) of memory device 200, transistors 261₀-261ᵢ of block 292 can be turned on (e.g., by activating respective signals SGD0′ through SGDi′) to couple the memory cell strings of block 292 to data lines 270₀-270_{N}. Transistors 261₀-261ᵢ of block 292 can be turned off (e.g., by deactivating respective signals SGD0′ through SGDi′) to decouple the memory cell strings of block 292 from respective sets of data lines 270₀-270_{N}.

Memory device 200 can include transistors (e.g., source select transistors) 260, each of which can be coupled between source 298 and the memory cells in a respective memory cell string of block 292. Transistors 260 of block 292 can share the same select gate (e.g., source select gate) 280′ of memory device 200. Transistors 260 of block 292 can be controlled (e.g., turned on or turned off) by the same signal, such as SGS′ signal (e.g., source select gate signal) provided on select gate 280′. During a memory operation (e.g., a read or write operation) of memory device 200, transistors 260 of block 292 can be turned on (e.g., by activating an SGS′ signal) to couple the memory cell strings of block 292 to source 298. Transistors 260 of block 292 can be turned off (e.g., by deactivating the SGS′ signal) to decouple the memory cell strings of block 292 from source 298. FIG. 2 shows select gates 280 and 280′ being electrically separated from each other as an example. Alternatively, select gates 280 and 280′ can be electrically coupled to each other.

Memory device 200 includes other components, which are not shown in FIG. 2 so as not to obscure the example embodiments described herein. Some of the structures of memory device 200 are described below with reference to FIG. 3A through FIG. 17. For simplicity, detailed description of the same element among the drawings (FIG. 1 through FIG. 17) is not repeated.

FIG. 3A shows a top view of a structure of memory device 200 including a memory cell array 201, staircase regions 345 and 346, dielectric structures 351A, 351B, 351C, 351D, and 351E between respective blocks 290, 291, 292, and 293, according to some embodiments described herein. In the figures (drawings) herein, similar or the same elements of memory device 200 of FIG. 2 and other figures (e.g., FIG. 3A through FIG. 17) are given the same labels. Detailed descriptions of similar or the same elements may not be repeated from one figure to another figure. For simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements shown in the drawings described herein are not scaled.

As shown in FIG. 3A, blocks (blocks of memory cells) 290, 291, 292, and 293 (290-293) of memory device 200 can be located side-by-side in the X-direction. Four blocks 290-293 are shown as an example. Memory device 200 can include numerous blocks. Blocks 291 and 292 of FIG. 3A are schematically shown and described above with reference to FIG. 2. Other blocks (e.g., block 290 and 293) of memory device 200 are not shown in FIG. 2.

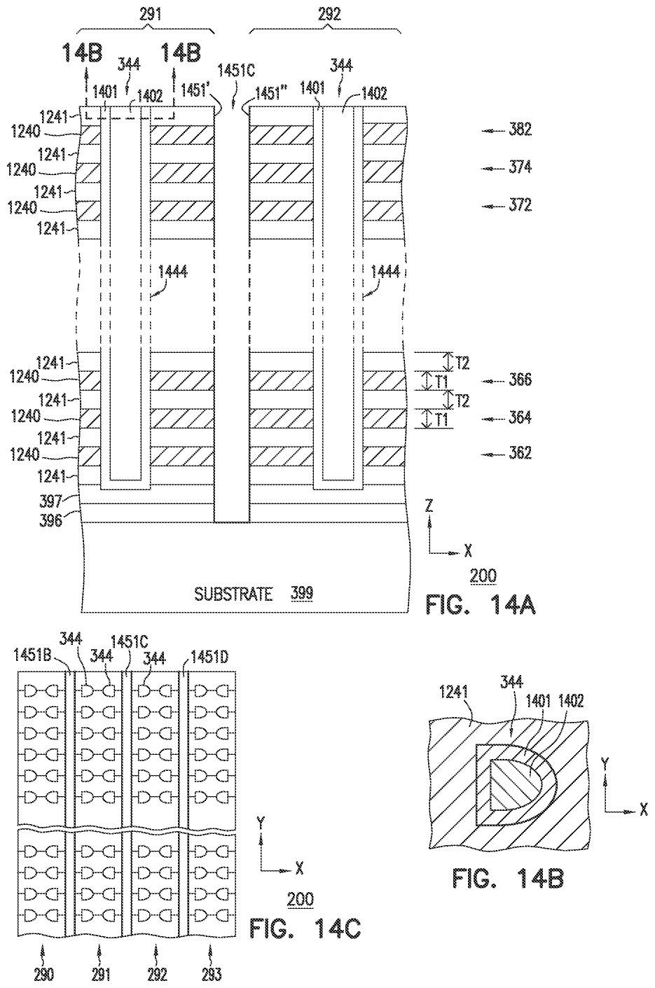

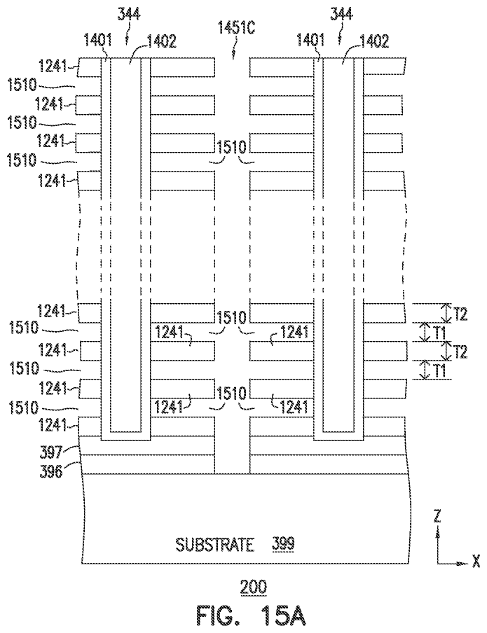

As shown in FIG. 3A, dielectric structures 351A, 351B, 351C, 351D, and 351E of memory device can have lengths extending in the Y-direction. Each of dielectric structures 351A, 351B, 351C, 351D, and 351E can be formed in a slit (not labeled) between two adjacent blocks. The slit can be similar to or the same as slit 1451C (FIG. 14). The slit can have sidewalls (e.g., edges) opposing each other in the X-direction and adjacent two respective blocks. The slit can include (or can be) a trench having a depth in the Z-direction.

In FIG. 3A, dielectric structure 351B can be formed (e.g., located) in a slit between blocks 290 and 291, in which the slit can have opposing sidewalls (e.g., edges) adjacent respective blocks 290 and 291. Dielectric structure 351C can be formed in a slit (e.g., slit 1451C in FIG.14) between blocks 291 and 292, in which the slit can have opposing sidewalls adjacent respective blocks 291 and 292. Other dielectric structures 351A, 351D, and 315E can be located adjacent respective blocks shown in FIG. 3A.

Each of dielectric structures 351A, 351B, 351C, 351D, and 351E can include a dielectric material (or dielectric materials) formed in (e.g., filling) a respective slit. Dielectric structures 351A, 351B, 351C, 351D, and 351E can electrically separate one block from another. For example, as shown in FIG. 3A, dielectric structure 351B can electrically separate block 291 from block 290. Dielectric structure 351C can electrically separate block 291 from block 292. Control gates and select gates of adjacent blocks can be electrically separated from each other by a dielectric structure between the adjacent blocks. For example, control gates 250₀ through 250_{M} (FIG. 2) and select gates 280 and 281₀ through 281ᵢ (FIG. 2) of block 291 (FIG. 2 and FIG. 3A) can be electrically separated from control gates 250′₀ through 250′_{M} (FIG. 2) and select gates 280′ and 281′₀ through 281′ᵢ (FIG. 2) of block 292 (FIG. 2 and FIG. 3A) by dielectric structure 351C (FIG. 3A)

As shown in FIG. 3A, memory device 200 can include pillars 330 (shown in top view) in blocks 290, 291, 292, and 293 coupled to respective data lines 270₀ through 270_{N}. Memory cells 202 of a memory cell string can be located (e.g., can be formed vertically) long the length (shown in FIG. 3B) of a corresponding pillar 330. Pillars 330 (and associated memory cell strings) of blocks 290-293 can share data lines 270₀ through 270_{N}.

As shown in FIG. 3A, data lines 270₀ through 270_{N} (associated with signals BL₀ through BL_{N}) of memory device 200 can be located over (above) pillars 330 (and over associated memory cell strings) in memory cell array 201. Data lines 270₀ through 270_{N} can be coupled to respective pillars 330 (which are located under data lines 270₀ through 270_{N} in the Z-direction). Data lines 270₀ through 270_{N} can have respective lengths extending in the X-direction. Data lines 270₀ through 270_{N} can extend over (e.g., on top of) and across (in the X-direction) blocks 290-293 and can be shared by blocks 290-293.

Staircase regions 345 and 346 of memory device 200 can be located on respective sides (in the Y-direction) of memory cell array 201. Staircase regions 345 and 346 can include conductive contacts to provide electrical connections (e.g., signals) to select gates and control gates (e.g., select gates 280, 281₀ and 281ᵢ and control gates 250₀ through 250_{M} of FIG. 2) in respective blocks 290, 291, 292, and 293 of memory device 200. Staircase regions 345 and 346 can include similar structures. However, for simplicity, details of staircase region 346 are omitted from FIG. 3A description herein. In an alternative structure of memory device 200, staircase region 346 can be omitted from memory device 200, such that only staircase region 345 (and not both staircase regions 345 and 346) is included in memory device 200.

As shown in FIG. 3A, in block 291, memory device 200 can include support structures 344 and conductive contacts 365_{SGS}, 365₀, 365₁, 365_{M}, 365_{M-1}, 365_{SGD0}, and 365_{SGDi} adjacent respective support structures 344. For simplicity, FIG. 3A does not give labels for all support structures and conductive contacts of blocks 290-293. As shown in FIG. 3A (e.g., viewing from a direction perpendicular to the X-Y plan), each conductive contact can have a circular shape.

For simplicity, FIG. 3A does not give labels for all support structures 344 of blocks 290-293. As shown in FIG. 3A, the boundary (e.g., perimeter) of each support structure 344 can include straight segments (e.g., three straight segments) and a curved segment (e.g., an arc) connected to straight segments to form a non-circular shape (not a shape of a circle). The shape of support structure 344 in FIG. 3A can be called a bullet shape.

As shown in FIG. 3A, conductive contacts 365_{SGS}, 365₀, 365₁, 365_{M}, 365_{M-1}, 365_{SGD0}, and 365_{SGDi} can have a circular shape. Thus, in the view (top view) memory device 200 in FIG. 3A, the shape (non-circular shape) of support structures 344 can be different from the shape (e.g., circular shape) conductive contacts 365_{SGS}, 365₀, 365₁, 365_{M}, 365_{M-1}, 365_{SGD0}, and 365_{SGDi}.

Memory device 200 can include conductive materials 340_{SGS}, 340₀, 340₁, 340_{M-1}, 340_{M}, 340_{SGD0}, and 340_{SGDi} in block 291 that can form (form the materials of) select gate 280, control gates 250₀ through 250_{M}, and select gates 280₀ and 280ᵢ, respectively, of FIG. 2. Conductive materials 340smo and 340_{SGDi} can be electrically separated from each other by a gap 347 (which can be filled with a dielectric material (or materials)). For simplicity, FIG. 3A does not give labels for other conductive materials that form select gates and control gates of block 290, 292, and 291. In FIG. 3A, line 3B-3B shows a location of a portion (e.g., a side view) of memory device 200 shown in FIG. 3B.

FIG. 3B shows of a portion (e.g., a cross-sectional side view) of memory device 200 shown along line 3B-3B of FIG. 3A. As shown in FIG. 3B, memory device 200 can include levels 362, 363, 364, 372, 374, and 382 that can be physical layers (e.g., portions) in the Z-direction of memory device 200. Conductive materials 340_{SGS}, 340₀, 340₁, 340_{M-1}, 340_{M}, 340_{SGD0}, and 340_{SGDi} can be located (e.g., stacked) one level (e.g., one layer) over another in respective levels 362, 364, 366, 372, 374, and 382 in the Z-direction. Conductive materials 340_{SGD0} and 340_{SGDi} (which form the drain select gates) can be located on the same level (e.g., level 382). Conductive materials 340_{SGS}, 340₀, 340₁, 340_{M-1}, 340_{M}, and 340_{SGDi} can be also called levels of conductive materials 340_{SGS}, 340₀, 340₁, 340_{M-1}, 340_{M}, and 340_{SGDi}.

As shown in FIG. 3B, conductive materials 340_{SGS}, 340₀, 340₁, 340_{M-1}, 340_{M}, and 340_{SGDi} can interleave with dielectric materials 341 in the Z-direction. Conductive materials 340_{SGS}, 340₀, 340₁, 340_{M-1}, 340_{M}, and 340_{SGDi} can include metal (e.g., tungsten, or other metal), other conductive materials, or a combination of conductive materials. Dielectric materials 341 can include silicon dioxide.

Signals SGS, WL₀, WL₁, WL_{M-1}, WL_{M}, SGD₀, and SGDᵢ in FIG. 3B associated with respective conductive materials in FIG. 3B are the same as the signals shown in FIG. 2. Conductive material 340sGs can form select gate 280 (associated with signal SGS) of FIG. 2. Conductive materials 340₀, 340₁, 340_{M-1}, and 340_{M} can form control gates 250₀ through 250_{M} (associated with signals WL₀, WL₁, WL_{M-1}, and WL_{M}, respectively) of FIG. 2. Conductive material 340_{SDG0} and 340_{SGDi} (associated with signals SGD₀, and SGDᵢ) can form select gates 280₀ and 280ᵢ, respectively, of FIG. 2.

As shown in FIG. 3B, conductive material 340₀ (which forms control gate 250₀ (FIG. 2) associated with signal WL₀) can be closest (in the Z-direction) to the substrate 399 relative to other conductive materials 340₁, 340_{M-1}, and 340_{M} that form other control gates 250₁ through 250_{M} (associated with signals WL_{M-1}, and WL_{M}) of memory device 200.

FIG. 3B shows an example of memory device 200 including one level of conductive material materials 340s_{G}s that forms a select gate (e.g., source select gate associated with signal SGS). However, memory device 200 can include multiple levels of conductive materials (e.g., multiple levels of conductive material 340_{SGS}) located under (in the Z-direction) the level of conductive materials 340₁ (e.g., below level 364) to form multiple source select gates of memory device 200.

FIG. 3B shows an example of memory device 200 including one level of conductive material materials 340smo that forms a select gate (e.g., drain select gate associated with signal SGD₀) and one level of conductive material materials 340_{SGDi} that forms a select gate (e.g., drain select gate associated with signal SGDᵢ). However, memory device 200 can include multiple levels of conductive materials (e.g., multiple levels of conductive material 340_{SGD0}) over (in the Z-direction) the level of conductive materials 340M (e.g., over level 374) to form multiple drain select gates similar to the select gate associated with signal SGD₀ of memory device 200. Similarly, memory device 200 can include multiple levels of conductive materials (e.g., multiple levels of conductive material 340_{SGDi}) over (in the Z-direction) the level of conductive materials 340M (e.g., over level 374) to form multiple drain select gates similar to the select gate associated with signal SGDᵢ of memory device 200.

As shown in FIG. 3B, memory device 200 can include staircase structure 333 located in staircase region 345 (FIG. 3A shows a top view of staircase region 345). For simplicity, only a portion of staircase structure 333 is shown in FIG. 3B (e.g., a middle portion of staircase structure 333 is omitted from FIG. 3B). As shown in FIG. 3B, respective portions (e.g., end portions) of conductive materials 340_{SGS}, 340₀, 340₁, 340_{M-1}, 340_{M}, and 340_{SDG1} and their respective edges (e.g., steps) 340E1, 340E2, and 340E3, 340E4, and 340E5 can collectively form staircase structure 333.

In FIG. 3B, a level of conductive material (e.g., conductive material 340₁) and an adjacent level of dielectric material 341 (e.g., dielectric material 341 between conductive materials 340₀ and 340₁) can be called a tier of memory device 200. As shown in FIG. 3B, the tiers can be located (e.g., stacked) one over another in the Z-direction over substrate 399. Each tier can have respective memory cells 202 and control gates (formed by conductive materials 340₀, 340₁, 340_{M-1}, and 340_{M}). FIG. 3B shows a few tiers of memory device 200 for simplicity. However, memory device 200 can include up to (or more than) one hundred tiers.

Other blocks (e.g., blocks 290, 292, and 293 in FIG. 3A) of memory device 200 can also have their own tiers of memory cells 202 and respective control gates for the memory cells, and staircase structures similar to staircase structure 333 block 291 in FIG. 3B. For simplicity, details of staircase structures of the other blocks (e.g., blocks 290, 292, and 293) of memory device 200 are omitted from the description herein.

As shown in FIG. 3B, dielectric materials 341 can also include edges (not labeled) adjacent (e.g., aligned in the Z-direction with) respective edges 340E1 through 340E5. Thus, staircase structure 333 can also be formed in part by portions and edges of dielectric materials 341.

As shown in FIG. 3B, memory device 200 can include a substrate 399 and materials 396 and 397 located over (e.g., formed over) substrate 399. Substrate 399 can include semiconductor (e.g., silicon) substrate. Substrate 399 can also include circuitry 395 located under other components of memory device 200 that are formed over substrate 399. Circuitry 395 can include circuit elements (e.g., transistors Tr1 and Tr2 shown in FIG. 3B) coupled to circuit elements outside substrate 399. For example, the circuit elements outside substrate 399 can include data lines 270₀ through 270_{N}, conductive contacts 365_{SGS}, 365₀, 365₁, 365_{M}, 365_{M-1}, 365_{SGD0}, and 365_{SGDi} (FIG. 3A), part of conductive paths 391 and other (not shown) conductive connections, and other circuit elements of memory device 200. The circuit elements (e.g., transistors Tr1 and Tr2) of circuitry 395 can be configured to perform part of a function of memory device 200. For example, transistors Tr1 and Tr2 can be part of decoder circuits, driver circuits, buffers, sense amplifiers, charge pumps, and other circuitry of memory device 200.

As shown in FIG. 3B, conductive paths (e.g., conductive routings) 391 can include portions extending in the Z-direction (e.g., extending vertically). Conductive paths 391 can include (e.g., can be coupled to) some (or all) of the conductive contacts of memory device 200 (e.g., conductive contacts 365_{SGS}, 365₁, 365_{M}, 365_{M-1}, 365_{SGD0}, and 365_{SGDi} in FIG. 3A). As shown in FIG. 3B, conductive paths 391 can be coupled to circuitry 395. For example, at least one of conductive paths 391 can be coupled to at least of one of transistors Tr1 and Tr2 of circuitry 395.

Conductive paths 391 can provide electrical connections between (e.g., conductive contacts 365_{SGS}, 365₁, 365_{M}, 365_{M-1}, 365_{SGD0}, and 365_{SGDi} in FIG. 3A) and other elements of memory device 200. For example, conductive paths 391 can be coupled to conductive contacts 365_{SGS}, 365₁, 365_{M}, and 365_{M-1} (and 365_{SGD0}, and 365_{SGDi}, not shown in FIG. 3B) and circuit elements (e.g., word line drivers and word line decoders, not shown) of circuitry 395 to provide electrical connection (e.g., in the form of signals SGS, WL₀, WL₁, WL_{M-1}, WL_{M}, SGD₀, and SGDᵢ) from circuit elements (e.g., word line drivers, word line decoders, and charge pumps, not shown) in circuitry 395 to conductive contacts 365_{SGS}, 365₀, 365₁, 365_{M}, 365_{M-1}, 365_{SGDi}, and 365_{SGD0}, respectively.

As shown in FIG. 3B, conductive contacts 365_{SGS}, 365₀o, 365₁, 365_{M}, and 365_{M-1} can include pillars that can have different lengths extending in the Z-direction (e.g., extending vertically (e.g., outward) from substrate 399). Each of conductive contacts (each of the pillars) 365_{SGS}, 365₀, 365₁, 365_{M}, and 365_{M-1} can contact (e.g., land on) a respective level of conductive material among conductive materials 340_{SGS}, 340₀, 340₁, 340_{M-1}, and 340_{M} to form an electrical contact with the respective level of conductive material. Thus, conductive contacts 365_{SGS}, 365₀, 365₁, 365_{M}, and 365_{M-1} (and 365_{SGD0}, and 365_{SGDi} shown in FIG. 3A) can be part of conductive paths (e.g., part of conductive paths 391) to carry electrical signals to the select gate (e.g., source select gate associated with signal SGS), the control gates (e.g., control gates associated with signals WL_{M} and WL_{M-1}) and other select gates (e.g., drain select gates associated with signals SGD₀ and SGDᵢ), respectively.

As shown in FIG. 3B, conductive contact 365_{SGS} is electrically in contact with conductive materials 340_{SGS} and electrically separated from the rest of conductive materials (e.g., conductive materials 340₀, 340₁, 340_{M-1}, 340_{M}, and 340_{SGDi}). Conductive contact 365o is electrically in contact with conductive materials 340₀ and electrically separated from the rest of conductive materials (e.g., conductive materials 340_{SGS}, 340₁, 340_{M-1}, 340_{M}, and 340_{SGDi}). Thus, a conductive contact (e.g., conductive contact 365o) can be electrically in contact with only one of the conductive materials among the conductive materials (e.g., conductive materials 340_{SGS}, 340₀, 340₁, 340_{M-1}, 340_{M}, 340_{SGD0}, and 340_{SGDi} in FIG. 3B) of memory device 200.

Materials 396 and 397 (FIG. 3B) can be part of source (e.g., a source line, a source plate, or a source region) 298 (FIG. 2) of memory device 200. Material 396 can include polysilicon. Material 397 can include tungsten oxide. Materials 396 and 397 can include other materials.

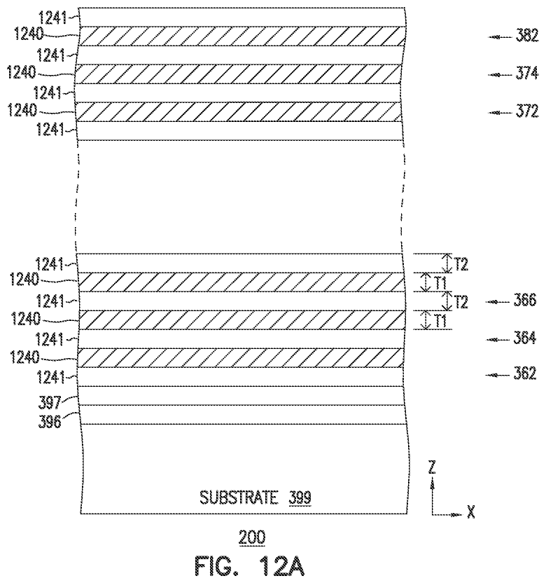

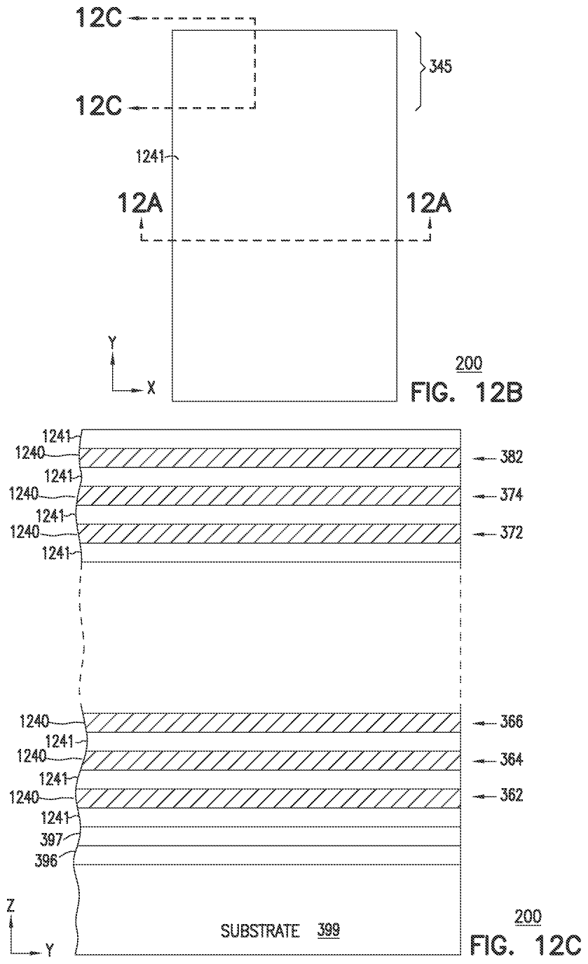

Support structures 344 can be formed to provide structural support to a portion (e.g., staircase region 345) of memory device 200 during particular processes of forming memory device 200, as described in more detail with reference to FIG. 12A through FIG. 16C.

As shown in FIG. 3B, support structures 344 can include pillars that have respective length extending in the Z-direction (e.g., extending vertically (e.g., outward) from substrate 399). Support structures 344 can have the same length. Support structures 344 can go through a respective portion of conductive materials 340_{SGS}, 340₀, 340₁, 340_{M-1}, and 340_{M} and dielectric materials 341. Support structures 344 are electrically separated from conductive materials 340_{SGS}, 340₀, 340₁, 340_{M-1}, and 340_{M}. Each of support structures 344 can contact (e.g., lands on) on material 397.

FIG. 3A shows a top view (e.g., viewing in a direction perpendicular to the X-Y plan) of support structures 344 having specific shape (e.g., non-circular shape (e.g., bullet shape)). However, support structures 344 can have other shapes.

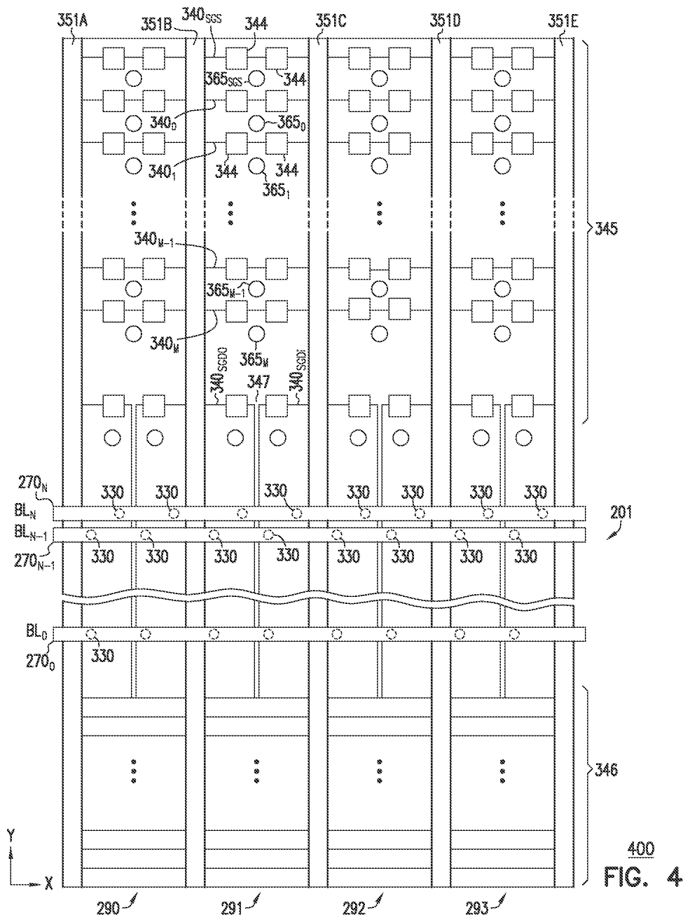

FIG. 4 through FIG. 7 show memory devices 400, 500, 600, and 700 including support structures having different shapes, according to some embodiments described herein. Memory devices 400, 500, 600, and 700 can have similar or the same elements as memory device 200 of FIG. 3A. Similar or the same elements between memory device 200 and the memory devices 400, 500, 600, and 700 are given the same labels and their descriptions are not repeated. Like FIG. 3A, support structures 344 of the memory devices shown in FIG. 4 through FIG. 7 can have a non-circular shape (with respect to a top view).

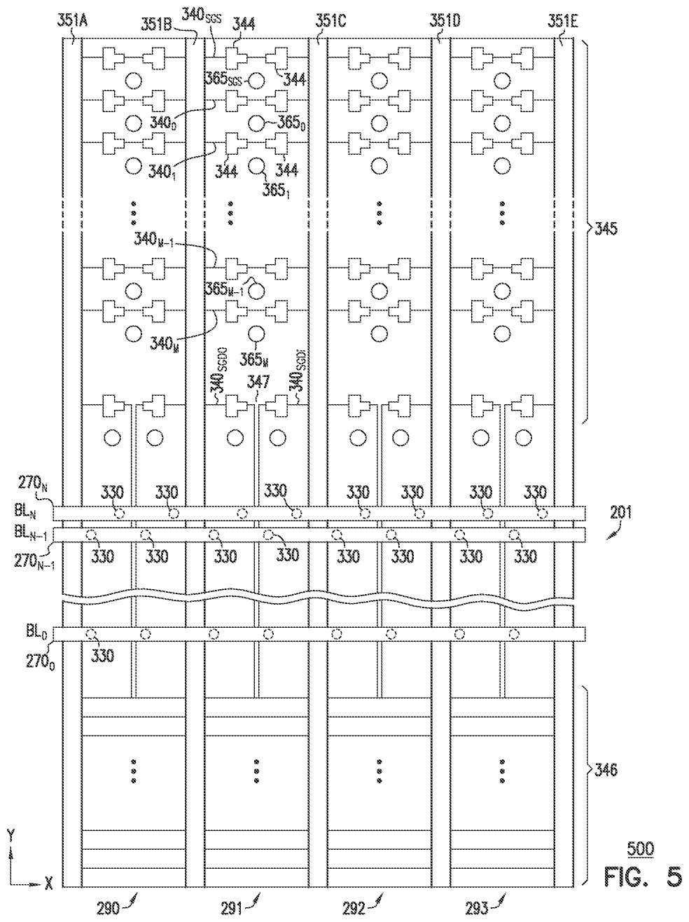

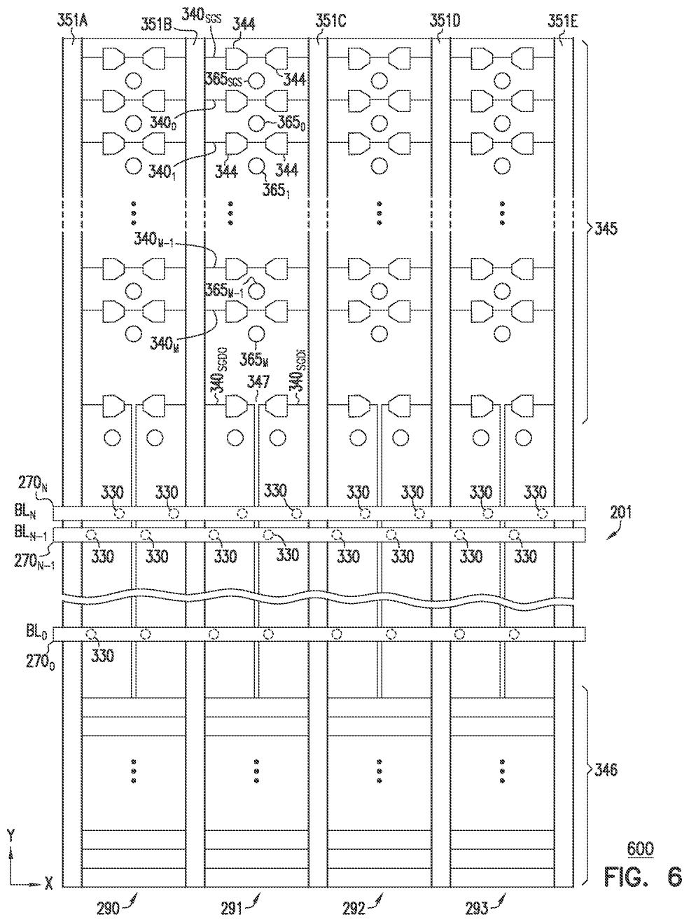

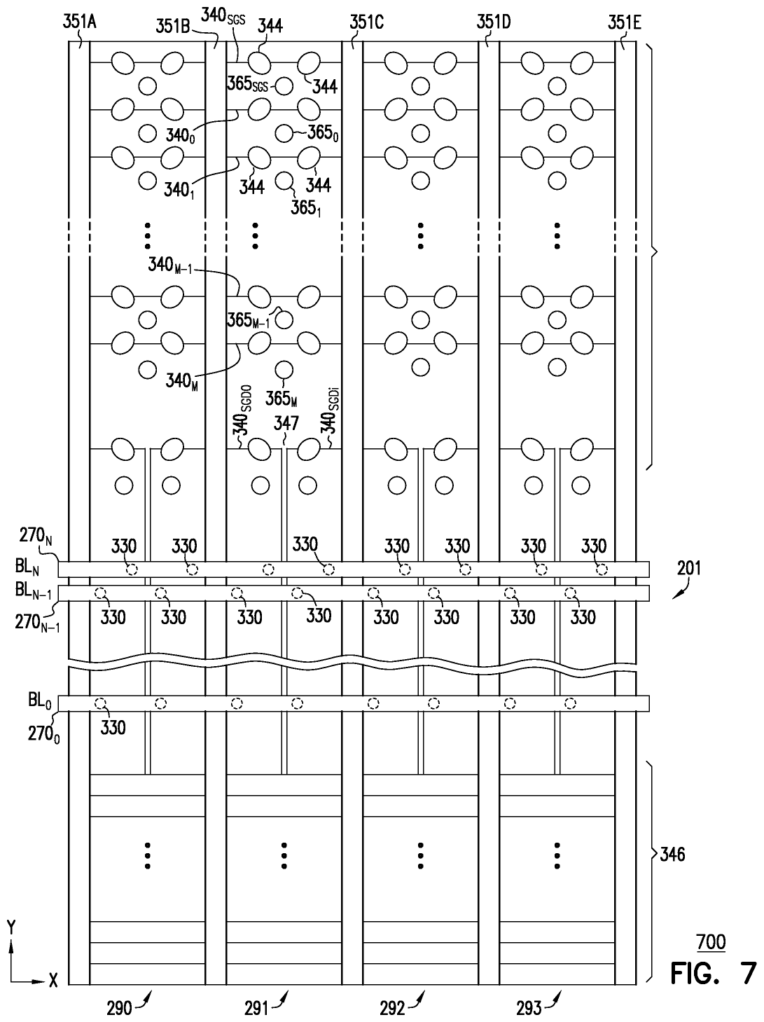

As shown in FIG. 4, the boundary (e.g., perimeter) of each support structure 344 of memory device 400 can include multiple straight sides (e.g., fourth straight sides) to form a rectangular shape (or alternatively a square). As shown in FIG. 5, the boundary (e.g., perimeter) of each support structure 344 of memory device 500 can include multiple straight sides (e.g., six straight sides) to form a T-shape. As shown in FIG. 6, the boundary (e.g., perimeter) of each support structure 344 of memory device 600 can include multiple sides (e.g., six sides) that can form a barn shape. The shape of support structures 344 in FIG. 5, FIG. 6, and FIG. 7 are examples of a polygon. As shown in FIG. 7, the boundary (e.g., perimeter) of each support structure 344 of memory device 700 can include an elliptical shape. FIG. 3A and FIG. 4 through FIG. 7 show some examples of non-circular shapes for support structures 344. However, support structures 344 can be formed to have other non-circular shapes.

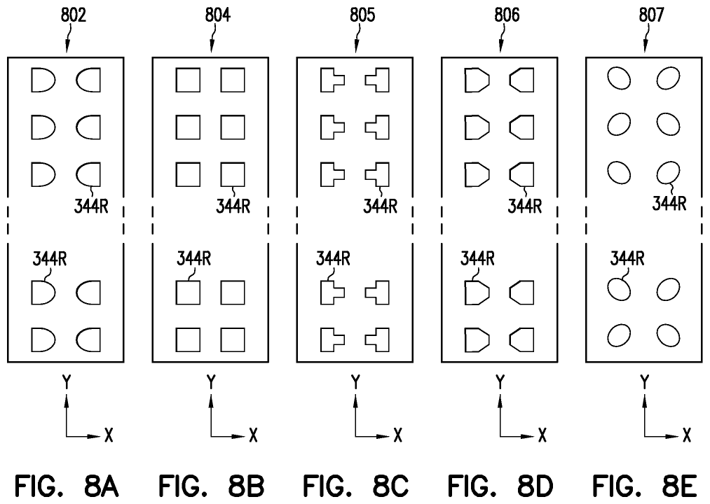

FIG. 8A through FIG. 8E show reticles (e.g., masks) 802, 804, 805, 806, and 807, according to some embodiments described herein. Reticles 802, 804, 805, 806, and 807 can be used (e.g., used in a lithography equipment) during part of the processes of forming support structures 344 of memory device 200, 400, 500, 600, and 700, respectively.

As shown in FIG. 8A through FIG. 8E, reticles 802, 804, 805, 806, and 807 can be designed (e.g., structured), such that they can include regions 334R having shapes like the shape of support structures 344 described above with reference to FIG. 3A through FIG. 7. The shapes of support structures 344 of memory device 200, 400, 500, 600, and 700 are intended shapes based on the shapes of regions 334R of reticles 802, 804, 805, 806, and 807, respectively. For example, reticle 802 in FIG. 8A can be used during part of the processes of forming support structures 344 of memory device 200. Thus, as shown in FIG. 3A, the shape (e.g., bullet shape) of support structures 344 are based on the shape (e.g., bullet shape) of regions 344R of reticle 802 of FIG. 8A.

The shapes of support structures 344 shown in FIG. 3A and FIG. 4 through FIG. 7 can provide improvements and benefits to respective memory devices 200, 400, 500, 600, and 700. For example, memory devices 200, 400, 500, 600, and 700 can be formed by processes that can be similar to or the same as the processes of forming the memory device described below with reference to FIG. 12A through FIG. 16C. In such processes, the tiers at some locations (at staircase region 345 in FIG. 3A) of the memory device are susceptible to bending (e.g., due to stiction or other factors). Too much tier bending can lead to tier collapse. Tier bending can be reduced by structuring the support structures (support structures 344 in FIG. 3A and FIG. 4 through FIG. 7) of the memory device with specific shapes (e.g., the shapes shown in FIG. 3A and FIG. 4 through FIG. 7). Reduction in tier bending can prevent tier collapse and can lead to improved yield, reliability, or both of the memory device described herein. The support structures 344 of the memory devices described above can be formed with a circular shape. However, forming support structures 344 with a circular shape may provide less reduction in tier bending than forming support structures 344 having a non-circular shape as described above with reference to FIG. 3A through FIG. 8E. Less reduction in tier bending (e.g., by forming support structures 344 having a non-circular shape) can increase the chance of tier collapsing.

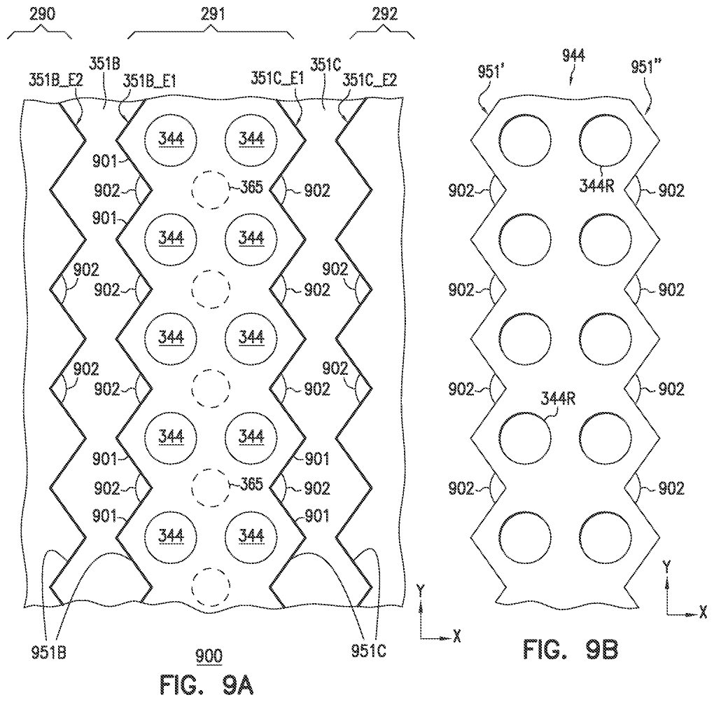

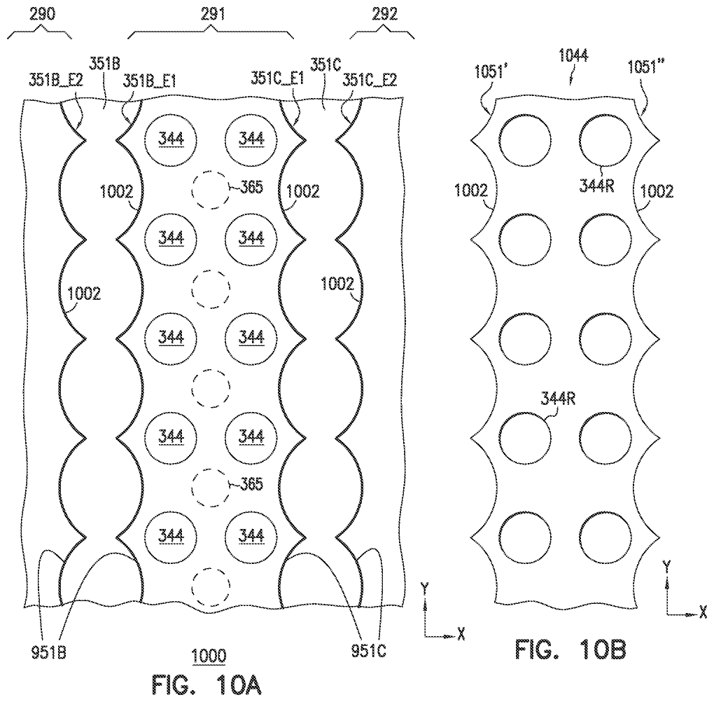

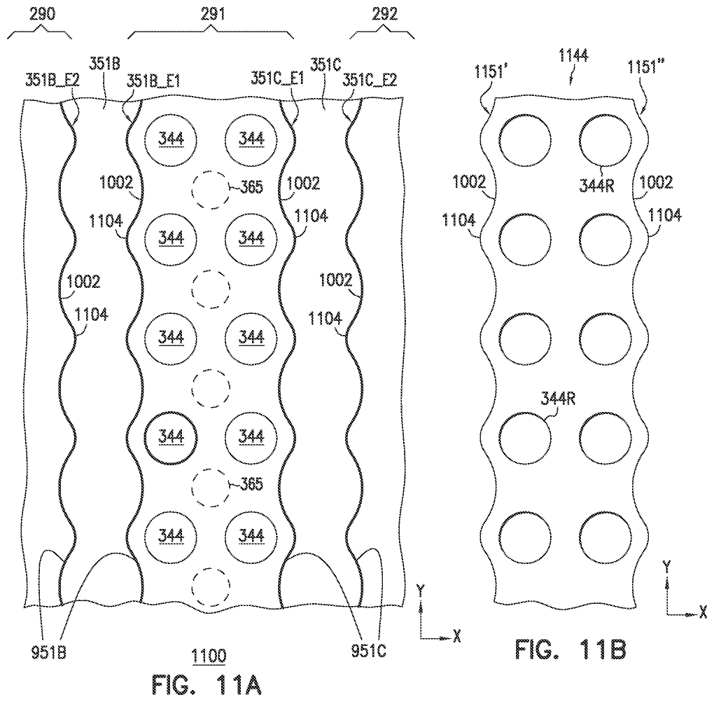

FIG. 9A, FIG. 10A, and FIG. 11A show portions of respective memory devices 900, 1000, and 1100 including slits 951B and 951C, dielectric structures 351B and 351C formed in respective slits 951B and 951C, in which slits 951B and 951C and structures 351B and 351C can have edges with a repeating pattern of a shape, according to some embodiments described herein. Memory devices 900, 1000, and 1100 can include elements similar to or the same as memory device 200 (FIG. 3). For simplicity, only a portion of each of memory devices 900, 1000, and 1100 are shown in FIG. 9A, FIG. 10A, and FIG. 11A, respectively, so as to not obscure the embodiments of the memory devices described herein. FIG. 9B, FIG. 10B, and FIG. 11B show reticles 944, 1044, and 1144, respectively, that can be used during part of forming slits 951B and 951C and forming support structures 344 memory respective devices 900, 1000, and 1100, according to some embodiments described herein.

In FIG. 9A, FIG. 10A, and FIG. 11A, dielectric structures 351B and 351C are similar to dielectric structures 351B and 351C of memory device 200 of FIG. 3A. Differences between dielectric structures 351B and 351C of memory device 200 and each of memory devices 900, 1000, and 1100 include the shapes of the edges of dielectric structures 351B and 351C in memory devices 900, 1000, and 1100. As shown in FIG. 9A, FIG. 10A, and FIG. 11A, edges 351B_E1, 351B_E2, 351C_E1 and 351C_E2 can have respective segments that collectively form a repeating pattern of a particular shape (e.g., a zigzag shape). The repeating pattern of a shape is intentionally formed (e.g., formed by design), for example, formed in part by using respective reticles 944, 1044, and 1144 shown in FIG. 9B, FIG. 10B, and FIG. 11B.

As shown in FIG. 9A, dielectric structure 351B can include edges 351B_E1 and 351B_E2 opposite from each other in the X-direction. Memory device 900 can include blocks 290, 291, and 292 like memory device 200 of FIG. 3A. As shown in FIG. 9A, edges 351B_E2 and 351B_E1 can be adjacent blocks 290 and 291, respectively. Edges 351C_E1 and 351C_E2 can be adjacent blocks 291 and 292, respectively.

In FIG. 9A, edges 351B_E1 and 351B_E2 can be adjacent respective sidewalls (e.g., edges) along the length (in the Y-direction) of slit 951B. Edge 351B_E1 of dielectric structure 351B can be at the location (e.g., at an interface along in the Y-direction) where the materials (e.g., conductive materials 340_{SGS}, 340₀, 340₁, 340_{M-1}, 340_{M}, and 340_{SGD0} in FIG. 3A) of block 291 are adjacent (e.g., contacting or indirectly contacting) the dielectric material (or dielectric materials) of dielectric structure 351B. Edge 351B_E2 of dielectric structure 351B can be at the location (e.g., at an interface along in the Y-direction) where the materials (e.g., conductive materials) of block 290 are adjacent (e.g., contacting or indirectly contacting) the dielectric material (or dielectric materials) of dielectric structure 351B.

Edges 351C_E1 and 351C_E2 of dielectric structure 351C can be adjacent respective sidewalls (e.g., edges) along the length (in the Y-direction) of slit 951C. Edge 351C_E1 of dielectric structure 351C can be at the location (e.g., at an interface along the Y-direction) where the materials (e.g., conductive materials 340_{SGS}, 340₀, 340₁, 340_{M-1}, 340_{M}, and 340_{SGD1} in FIG. 3A) of block 291 are adjacent (e.g., contacting or indirectly contacting) the dielectric material (or dielectric materials) of dielectric structure 351C. Edge 351C_E2 of dielectric structure 351C can be at the location (e.g., at an interface along the Y-direction) where the materials (e.g., conductive materials) of block 292 are adjacent (e.g., contacting or indirectly contacting) the dielectric material (or dielectric materials) of dielectric structure 351B.

As shown in FIG. 9A, each of edges 351B_E1, 351B_E2, 351C_E1 and 351C_E2 can include segments (e.g., straight segments) 901 that collectively form a repeating pattern of a particular shape (e.g., a zigzag shape). As shown in FIG. 9A, two adjacent segments 901 can be connected to each other and form an angle 902. Angle 902 can be greater than zero degrees and less than 180 degrees (e.g., 0°<angle 902<180°). In some structures of memory device 900, a repeating pattern having angle 902 with a higher degree can provide more improvement (e.g., lesser tier bending) than a repeating pattern having angle 902 with a lower degree. As shown in FIG. 9A, the repeating patterns of edges 351B_E1 and 351B_E2 can be symmetrical (e.g., mirrored) with respect to the X-direction. However, the repeating patterns of edges 351B_E1 and 351B_E2 may be non-symmetrical (e.g., asymmetrical) with respect to the X-direction. Similarly, patterns of edges 351C_E1 and 351C_E2 can be symmetrical (as shown in FIG. 9A) or non-symmetrical.

As shown in FIG. 9A, block 291 of memory device 900 can include conductive supports 344 and conductive contacts 365 (which can correspond to some of conductive contacts 365_{SGS}, 365₀, 365₁, 365_{M}, and 365_{M-1} of FIG. 3). FIG. 9A shows an example where conductive supports 344 have a circular shape (with respect to a top view (e.g., viewing from a direction perpendicular to the X-Y plan)). However, conductive supports 344 can have any of the shapes (e.g., bullet, polygon (e.g., rectangular, T-shape, and barn shape), and elliptical) of conductive supports 344 described above with reference to FIG. 3A through FIG. 7.

Reticle 944 in FIG. 9B can be used during part of the processes of forming slits (e.g., slits 951B and 951C in FIG. 9A) and support structures (e.g., support structures 344 in FIG. 9A) of memory device 900. As shown in FIG. 9B, reticle 944 can include regions 344R having a circular shape. However, reticle 944 can include regions 344R having other shapes. For example, reticle 944 can include regions 344R having any of the shapes (e.g., bullet, polygon (e.g., rectangular, T-shape, and barn shape), and elliptical) like the shapes of reticles 802, 804, 805, 806, and 807 described above with reference to FIG. 8A through FIG. 8E, respectively.

As shown in FIG. 9B, reticle 944 can include edges 951′ and 951″ having a repeating pattern of a shape formed by segments 901. The shape of the edges of slits 951B and 951C and dielectric structures 351B and 351C of memory device 900 (FIG. 9A) can be based on the shape of edges 951′ and 951″ of reticle 944.

As shown in FIG. 10A, memory device 1000 can have elements that are similar to or the same as the elements of memory device 900 of FIG. 9A, including blocks 290, 291, and 292, dielectric structures 351B and 351C, and edges 351B_E1, 351B_E2, 351C_E1, and 351C_E2, support structures 344, and conductive contacts 365. For simplicity, detailed description of similar or the same elements between memory devices 900 and 1000 are not repeated. Differences between memory devices 900 and 1000 include the shapes of the edges of dielectric structures 351B and 351C in memory device 1000.

As shown in FIG. 10A, each of edges 351B_E1, 351B_E2, 351C_E1 and 351C_E2 can include curved segments 1002 that form a repeating pattern of a particular shape (e.g., a zigzag shape). In some structures of memory device 1000, a repeating pattern having curved segments 1002 with a higher curvature (e.g., more concave into the block) can provide more improvement (e.g., lesser tier bending) than repeating pattern having curved segments 1002 with a lower curvature (e.g., less concave into the block). As shown in FIG. 10A, the repeating patterns of edges 351B_E1 and 351B_E2 can be symmetrical (e.g., mirrored) with respect to the X-direction. However, the repeating patterns of edges 351B_E1 and 351B_E2 may be non-symmetrical (e.g., asymmetrical) with respect to the X-direction. Similarly, patterns of edges 351C_E1 and 351C_E2 can be symmetrical (as shown in FIG. 10A) or non-symmetrical.

FIG. 10A shows an example where conductive supports 344 have a circular shape (with respect to a view (e.g., top view) perpendicular to the X-Y plan). However, conductive supports 344 can have any of the shapes (e.g., bullet, polygon (e.g., rectangular, T-shape, and barn shape), and elliptical) of conductive supports 344 described above with reference to FIG. 3A through FIG. 7.

Reticle 1044 of FIG.10B can be used during part of the processes of forming slits (e.g., slits 951B and 951C in FIG. 10A) and support structures (e.g., support structures 344 in FIG. 10A) of memory device 1000. As shown in FIG. 10B, reticle 1044 can include regions 344R having a circular shape. However, reticle 1044 can include regions 344R having other shapes. For example, reticle 1044 can include regions 344R having any of the shapes (e.g., bullet, polygon (e.g., rectangular, T-shape, and barn shape), and elliptical) like the shapes of reticles 802, 804, 805, 806, and 807 described above with reference to FIG. 8A through FIG. 8E, respectively.

As shown in FIG. 10B, reticle 1044 can include edges 1051′ and 1051″ having a repeating pattern of a shape formed by curved segments 1002. The shape of the edges of slits 951B and 951C and dielectric structures 351B and 351C of memory device 1000 (FIG. 10A) can be based on the shape of edges 1051′ and 1051″ of reticle 1044.

As shown in FIG. 11A, memory device 1100 can have elements that are similar to or the same as the elements of memory device 900 of FIG. 9A, including blocks 290, 291, and 292, dielectric structures 351B and 351C, and edges 351B_E1, 351B_E2, 351C_E1, and 351C_E2, support structures 344, and conductive contacts 365. For simplicity, detailed description of similar or the same elements between memory devices 900 and 1100 are not repeated.

As shown in FIG. 11A, like FIG. 10A, each of edges 351B_E1, 351B_E2, 351C_E1 and 351C_E2 can include curved segments 1002 that are part of a repeating pattern of a particular shape (e.g., a zigzag shape). However, as shown in FIG. 11A, each of edges 351B_E1, 351B_E2, 351C_E1 and 351C_E2 can include curved segments 1104 between respective curved segments 1002. In comparison with FIG. 10A, a sharp corner between two adjacent curved segments 1002 is replaced by a respective curved segment 1104. As shown in FIG. 11A, the repeating patterns of edges 351B_E1 and 351B_E2 can be symmetrical (e.g., mirrored) with respect to the X-direction. However, the repeating patterns of edges 351B_E1 and 351B_E2 may be non-symmetrical (e.g., asymmetrical) with respect to the X-direction. Similarly, patterns of edges 351C_E1 and 351C_E2 can be symmetrical (as shown in FIG. 11A) or non-symmetrical.

FIG. 11A shows an example where conductive supports 344 have a circular shape (with respect to the view (e.g., top view) perpendicular to the X-Y plan). However, conductive supports 344 can have any of the shapes (e.g., bullet, polygon (e.g., rectangular, T-shape, and barn shape), and elliptical) of conductive supports 344 described above with reference to FIG. 3A through FIG. 7.

Reticle 1144 in FIG. 11B can be used during part of the processes of forming slits (e.g., slits 951B and 951C in FIG. 11A) and support structures (e.g., support structures 344 in FIG. 11A) of memory device 1100. As shown in FIG. 11B, reticle 1144 can include regions 344R having a circular shape. However, reticle 1144 can include regions 344R having other shapes. For example, reticle 1144 can include regions 344R having any of the shapes (e.g., bullet, polygon (e.g., rectangular, T-shape, and barn shape), and elliptical) like the shapes of reticles 802, 804, 805, 806, and 807 described above with reference to FIG. 8A through FIG. 8E, respectively.

As shown in FIG. 11B, reticle 1144 can include edges 1151′ and 1151″ having a repeating pattern of a shape formed by curved segments 1002 and 1104. The shape of the edges of slits 951B and 951C and dielectric structures 351B and 351C of memory device 1100 (FIG. 11A) can be based on the shape of edges 1151′ and 1151″ of reticle 1144.

The shapes of the edges of slits 951B and 951C and dielectric structures 351B and 351C shown in FIG. 9A, FIG. 10A, and FIG. 11A can provide improvements and benefits to respective memory devices 900, 1000, and 1100. For example, memory devices 900, 1000, and 1100 can be formed by processes that can be similar to or the same as the processes of forming the memory device described below with reference to FIG. 12A through FIG. 16C. In such processes, the tiers at some locations (at staircase region 345 in FIG. 3A) of the memory device are susceptible to bending (e.g., due to stiction or other factors). Too much tier bending can lead to tier collapse. Tier bending can be reduced by structuring the slits (e.g., slits 951B and 951C in FIG. 9A, FIG. 10A, and FIG. 11A) between the blocks and dielectric structures (dielectric structures 351B and 351C in FIG. 9A, FIG. 10A, and FIG. 11A) of the memory device with edges having specific shapes (e.g., the repeating patterns of shapes shown in FIG. 9A, FIG. 10A, and FIG. 11A). Reduction in tier bending can prevent tier collapse and can lead to improved yield, reliability, or both of the memory device described herein.

The slits and the dielectric structures (slits 951B and 951C and dielectric structures 351B and 351C in FIG. 9A, FIG. 10A, and FIG. 11A) of the memory devices (e.g., memory device 900, 1000, and 1100) described above can be formed with edges having a non-repeating pattern of a shape (e.g., formed with straight edges). However, forming such slits and dielectric structures having a non-repeating pattern of a shape (e.g., with straight edges) may provide less reduction in tier bending than forming slits and dielectric structures with edges having specific shapes (e.g., the repeating patterns shown in FIG. 9A, FIG. 10A, and FIG. 11A). Less reduction in tier bending (e.g., by forming the dielectric structures having a non-repeating patter) can increase the chance of tier collapse.

The memory devices described above with reference to FIG. 1 through FIG. 11B including slits between blocks, dielectric structures (e.g., dielectric structures 351B through 351E), and the support structures (e.g., support structures 344) can be formed using processes similar to or the same as the processes described below with reference to FIG. 12A through FIG. 16C.

FIG. 12A through FIG. 16C show different views of structures during processes of forming memory device 200 of FIG. 2 through FIG. 3B, according to some embodiments described herein. FIG. 12A shows a side view in the X-Z directions of device 200 after dielectric materials (levels of dielectric materials) 1240 and dielectric materials (levels of dielectric materials) 1241 are alternatively formed over substrate 399. Dielectric materials 1240 and dielectric materials 1241 can be sequentially formed one material after another over substrate 399 in an interleaved fashion.

As shown in FIG. 12A, a level (e.g., a single layer) of dielectric materials 1240 can have a thickness T1. A level (e.g., a single layer) of dielectric materials 1241 can have a thickness T2. In an example, thickness T1 can be 32 nm and can have a range from 30 nm to 35 nm, and thickness T2 can be 25 nm and can have a range from 22 nm to 27 nm. Thicknesses T1 and T2 can have other values.

Dielectric materials 1240 can include silicon nitride. Dielectric materials 1241 can include silicon dioxide. As shown in FIG. 12A, dielectric materials 1240 and 1241 can be formed, such that dielectric materials 1240 can interleave with dielectric materials 1241 in the Z-direction on respective levels 362, 364, 366, 372, 374, and 382. For simplicity, FIG. 12A omits some of dielectric materials 1240 and 1241 between levels 366 and 372.

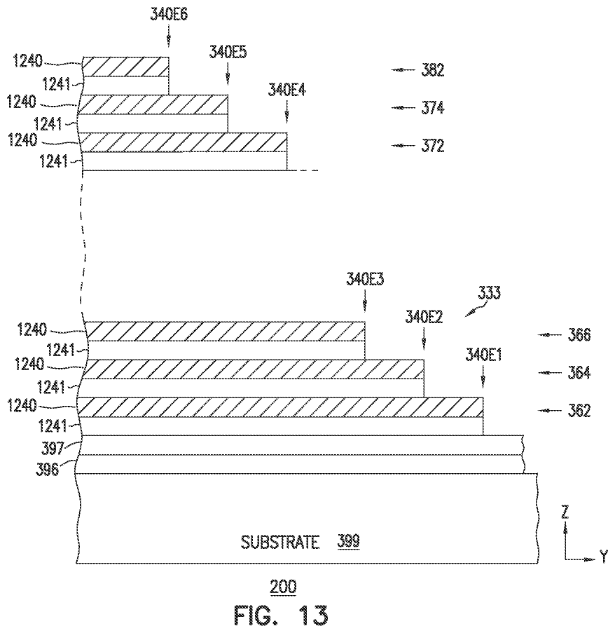

FIG. 12B shows a top view (e.g., X-Y plan) of memory device 200 of FIG. 12A. FIG. 12B also shows the location of staircase region 345 (which is also shown in FIG. 3A). Staircase structure 333 (FIG. 3B) in staircase region 345 can be formed using the processes associated with FIG. 13. In FIG. 12B, line 12A-12A shows a location of the portion (e.g., a cross-sectional side view in the X-Z direction) of memory device 200 shown in FIG. 12A. FIG. 14A (described below) is also taken along line 12A-12A of FIG. 12B. Line 12C-12C in FIG. 12B shows a location of a portion (e.g., a cross-sectional side view in the Y-Z direction) of staircase region 345 of memory device 200 shown in FIG. 12C.

As shown in FIG. 12C, the interleaved formation of dielectric materials 1240 and 1241 shown in the Y-Z direction can be the same as the interleaved formation of dielectric materials 1240 and 1241 shown in the X-Z direction (shown in FIG. 12A).

FIG. 13 shows memory device 200 of FIG. 12C (in the Y-Z direction) after staircase structure 333 is formed. Forming staircase structure 333 can include removing a portion of dielectric materials 1240 and 1241 to obtain a remaining portion of dielectric materials 1240 and 1241 having respective edges (e.g., vertical edges) 340E1 through 340E6, at respective levels among levels 362, 364, 366, 372, 374, and 382.

FIG. 14A shows a side view of memory device 200 after formation of support structures 344 of blocks 291 and 392, and a slit (e.g., a trench) 1451C between blocks 291 and 292. The side view (in the X-Z direction) of memory device 200 in FIG. 14A is the same as the side view (in the X-Z direction) of memory device 200 in FIG. 12A. Slit 1451C in FIG. 14A can be formed after support structures 344 are formed. For simplicity, only two support structures 344 are shown in FIG. 14A. Other support structures 344 of memory device 200 can be formed in similar fashion and can be formed concurrently (e.g., formed in the same process step).

In FIG. 14A, forming support structures 344 can include removing portions of dielectric materials 1240 and 1241 to form openings (e.g., holes) 1444 at the locations where support structures 344 are formed. After openings 1444 are formed, materials (liners) 1401 can be formed on sidewalls of openings 1444. Then, material (e.g., core) 1402 can be formed (e.g., filled) in openings 1444. Line 14B-14B in FIG. 14A shows a portion (e.g., cross-section) of a support structure 344 that is shown in FIG. 14B.

In FIG. 14B, the cross-section of support structure 344 is taken (e.g., cut) along line 14B-14B (FIG. 14A) in a direction perpendicular to the direction (e.g., Z-direction) of the length of support structure 344. Thus, the cross-section of support structure 344 in FIG. 14B is viewed from a direction perpendicular to the X-Y plan (as shown in FIG. 14B). As shown in FIG. 14B, material 1402 can be separated from other elements (e.g., from dielectric material 1241) of memory device 200 by material 1401. Material 1401 can include a single dielectric material (silicon dioxide or silicon nitride) or combination (e.g., different layers) of materials (e.g., a combination of silicon dioxide and silicon nitride). Material 1402 can include a single material or a combination (e.g., different layers) of materials. Examples for material 1402 include metal, polysilicon, or other materials.

As shown in FIG. 14B, the boundary (e.g., perimeter) of support structure 344 can have a bullet shape. The shape (e.g., bullet shape) of the support structure 344 shown in FIG. 14B can be based on the shape of openings 1444 (FIG. 14A) with respect to the X-Y plan. The shape of openings 1444 can be based on the shape of a region of a reticle used during formation of openings 1444. For example, reticle 802 (FIG. 8A) can be used during part of forming openings 1444 (FIG. 14A). Thus, the shape (e.g., bullet shape) of support structure 344 shown in FIG. 14B can be based on the shape (e.g., bullet shape) of regions 344R of reticle 802.

FIG. 14B shows one example of a non-circular shape of support structure 344. However, support structure 344 of FIG. 14B can have other non-circular shapes. For example, any of reticles 804, 805, 806, and 807 (FIG. 8B through FIG. 8E) can be used during part of forming support structures 344 (FIG. 14A), such that the shape of support structure 344 in FIG. 14B can be based on the shapes of regions 344R of any of reticles 804, 805, 806, and 807 (FIG. 8B through FIG. 8E).

In FIG. 14A, forming slit 1451C (FIG. 14A) can include removing a portion of dielectric materials 1240 and 1241 to form an opening (e.g., a trench) at the location of slit 1451C, such that slit 1451C can include edges (e.g., sidewalls) 1451′ and 1451″, and a depth in the Z-direction. As shown in FIG. 14A, each of edges 1451′ and 1451″can include (e.g., can be formed by) respective sidewalls (not labeled) that can be part of dielectric materials 1240 and 1241 at the location of slit 1451C. Edges 1451′and 1451″ of slit 1451C can be adjacent edges 351C_E1 and 351C_E2 (FIG. 9A, FIG. 10A, and FIG. 11A), respectively, of dielectric structure 351C described above with reference to FIG. 9A, FIG. 10A, and FIG. 11A.

FIG. 14C shows memory device 200 after formation of support structures 344 and slits 1451B, 1451C, and 1451D between respective blocks 290, 291, 292, and 293 of memory device 200. For simplicity, slits 1451B and 1451D in FIG. 14C are not shown in FIG. 14A. In FIG. 14C, slits 1451B, 1451C, and 1451D can correspond to respective slits of memory device 200 (FIG. 3A) at the locations of dielectric structures 351B, 351C, and 351D (FIG. 3A).

FIG. 14C shows an example where slits 1451B, 1451C, and 1451D have straight edges (viewing from a direction perpendicular to the X-Y plan). However, the edges along the Y-direction (FIG. 14C) of slits 1451B, 1451C, and 1451D can have a repeating pattern of a shape like the edges of the slits 951B and 951C in FIG. 9A, FIG. 10A, and FIG. 11A. Thus, the edges of slits 1451B, 1451C, and 1451D, and support structures 344 can have any combination of a repeating pattern of a shape for the edges of the slits (e.g., repeating patterns shown in FIG. 9A, FIG. 10A, and FIG. 11A) and a shape for a support structure (e.g., the shapes of regions 344R shown in FIG. 8A through FIG. 8E) described above with reference to FIG. 3A through FIG. 11B.

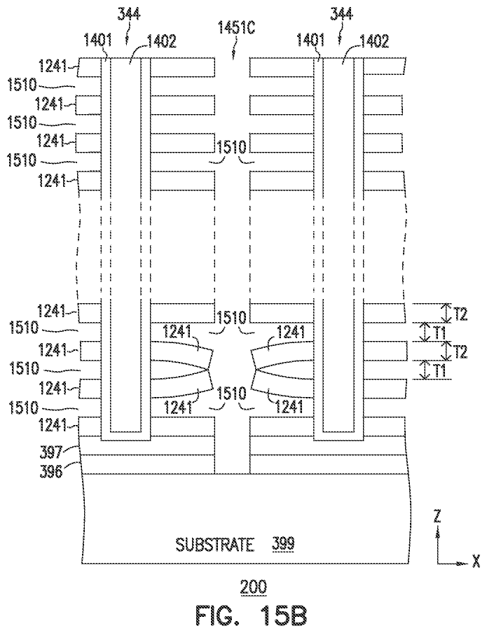

FIG. 15A shows memory device 200 after dielectric material 1240 (FIG. 14A) is removed (e.g., exhumed) from locations 1510 (FIG. 15A). Support structures 344 can provide structural support to prevent the higher levels of dielectric materials 1241 from falling down to lower levels of dielectric materials 1241 during the process of forming memory device 200 (e.g., during the process associated with the removal of dielectric materials 1240 (FIG. 14A) from the locations 1510 in FIG. 15A).

FIG. 15B shows memory device 200 in an example situation that includes a collapse of portions of dielectric materials 1241 at the location of slit 1451C. As shown in FIG. 15B, adjacent portions of dielectric materials 1241 can collapse, such that the adjacent portions of dielectric materials 1241 can touch (contact) each other.

At a certain values of thicknesses T1 and T2, collapse of dielectric materials 1241 at some locations (e.g., at staircase structure 333) of memory device 200 may occur (e.g., due to stiction). Such stiction may be caused by adjacent dielectric materials 1241 sticking to each other (e.g., upon experiencing capillary force caused by surface tension) causing the collapse of some of dielectric materials 1241 like the example situation shown in FIG. 15B. The collapse can cause conductive materials (e.g., conductive materials 340_{SGS}, 340₀, and 340₁ in FIG. 3B) formed in subsequent processes at the locations of collapse to short (e.g., electrically coupled to) each other. Such a short can degrade or destroy the function of memory device 200. To prevent such collapse and improve the structure and reliability of memory device 200, some of the elements of memory device 200 can be formed with specific geometries, such as repeating patterns and shapes described above with reference to FIG. 3A through FIG. 11B.

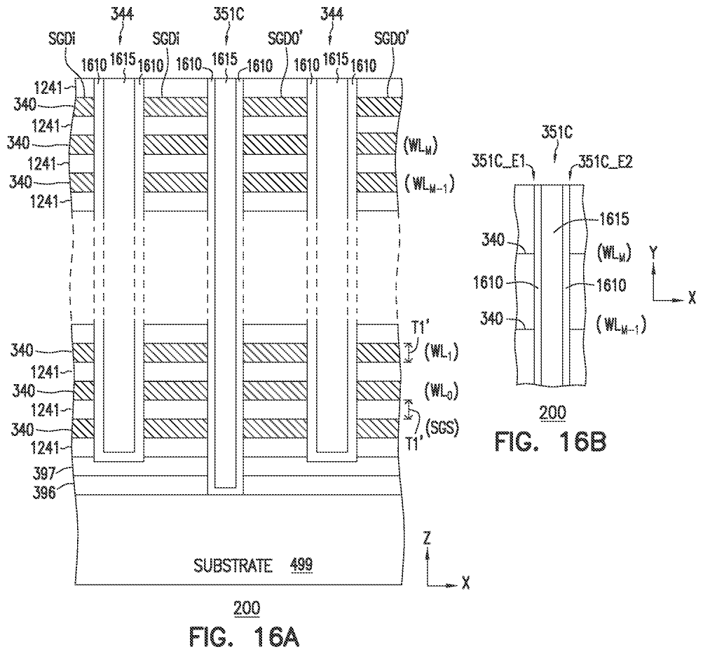

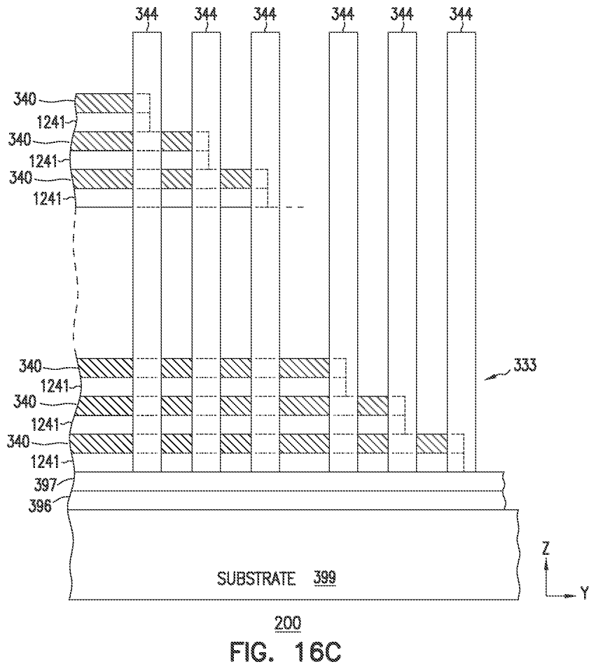

FIG. 16A shows memory device 200 of FIG. 15A after formation of conductive materials (e.g., levels of conductive materials) 340 and dielectric structure 351C. As shown in FIG. 16A, a level (e.g., a single layer) of conductive materials 340 can have thickness T1′. Thickness T1′ can be the same thickness T1 of a level of dielectric materials 1240 (FIG. 14A).

Conductive materials 340 can be formed by filling a material (or materials) in location 1510 (FIG. 15A). In an example, conductive materials 340 can include a single conductive material, for example, a single metal (e.g., tungsten). In another example, conductive materials 340 can include multiple materials (which can be formed one material after another). One of the multiple materials can include a conductive material (e.g., metal such as tungsten). For example, conductive materials 340 can include different layers of aluminum oxide (AlO), titanium nitride (TNi), and tungsten (W). Conductive materials 340 can correspond to conductive materials 340_{SGS}, 340₀, 340₁, 340_{M-1}, 340_{M}, 340_{SGD0}, and 340_{SGDi} shown in FIG. 3B. In FIG. 16A, signals SGS, WL₀, WL₁, WL_{M-1}, WL_{M}, SGD₀, and SGDᵢ associated with respective conductive materials 340 are the same as the signals shown in FIG. 3B. Dielectric materials 1241 in FIG. 16A can correspond to dielectric materials 341 of FIG. 3B.

In the processes associated with FIG. 16A, dielectric structure 351C can be formed by filling (e.g., depositing) a material (e.g., a liner) 1610 and a material 1615 in the location of slit 1415C (labeled in FIG. 15A). In FIG. 16A, material 1610 can include a dielectric material (e.g., silicon dioxide). Material 1615 can include polysilicon, or alternatively, a dielectric material (e.g., silicon dioxide or silicon nitride). As shown in FIG. 16A, material 1610 can be formed (e.g., located) adjacent sidewalls (e.g., vertical sidewalls) of respective material 340 and dielectric material 1241 at the location of dielectric structure 351C.

FIG. 16B shows a top view (in the X-Y direction) of a portion of memory device 200 of FIG. 16A at dielectric structure 351C. As shown in FIG. 16A and FIG. 16B, material 1610 and be formed on both sides (e.g., formed on opposite sidewalls in the X-direction, not labeled) of dielectric structure 351C. Material 1615 can be formed between portions (e.g., sidewall portions) of material 1610. Materials 1610 and 1615 can be formed along the length (in the Y-direction) of dielectric structure 351C.

FIG. 16C shows a side view (e.g., cross-sectional side view) of memory device 200 of FIG. 16A including support structures 344 (formed in the processes associated with FIG. 14A). After support structures (e.g., support structures 344) of memory device 200 are formed, conductive contacts 365_{SGS}, 365₁, 365_{M}, 365_{M-1}, 365_{SGD0}, and 365_{SGDi} (FIG. 3A and FIG. 3B) can be formed in subsequent processes of memory device 200. Then, additional processes can be performed to complete formation of memory device 200. For simplicity and to not obscure the embodiments described herein, subsequent processes to complete memory device 200 are not described herein.

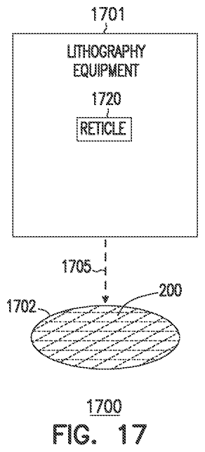

FIG. 17 shows a system 1700 including lithography equipment (e.g., a stepper) 1701 and reticle 1720, according to some embodiments described herein. System 1700 can be used in part of the process of forming memory device 200. For example, lithography equipment 1701 can be used to pass a light source (not shown) through reticle 1720. Then, a projection lens (not shown) of lithography equipment 1701 can receive the light source (after the light source passes through reticle 1720) and produce a light beam 1705 based on the light source. The projection lens can project light beam 1705 onto a wafer 1702 during formation of some of the structures (e.g., the dielectric structures and the support structures described above) of memory device 200, which can be a portion of a wafer 1702. Reticle 1720 can include any of the reticles described above or any combination of the reticles described above (e.g., FIG. 8A through FIG. 8E and FIG. 9B, FIG. 10B, and FIG. 11B). Benefits and improvements to the dielectric structures and the support structures (e.g., formed by using reticle 1720 in system 1700) are described above with reference to FIG. 3A through FIG. 16C.

The illustrations of apparatuses (e.g., memory devices 100, 200, 400, 500, 600, 700, 900, 1000, and 1100) and methods (e.g., methods of forming memory device 200) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 400, 500, 600, 700, 900, 1000, and 1100) or a system (e.g., an electronic item that can include any of memory devices 100, 200, 400, 500, 600, 700, 900, 1000, and 1100)

Any of the components described above with reference to FIG. 1 through FIG. 17 can be implemented in a number of ways, including simulation via software. Thus, apparatuses (e.g., memory devices 100, 200, 400, 500, 600, 700, 900, 1000, and 1100), or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The memory devices (e.g., memory devices 100, 200, 400, 500, 600, 700, 900, 1000, and 1100) described herein may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 17 include apparatuses and methods of forming the apparatuses. One of the apparatuses includes first tiers located one over another, the first tiers including respective first memory cells and first control gates for the memory cells, the first memory cells located along respective first pillars, the first pillars extending through the first tiers; second tiers located one over another, the second tiers including respective second memory cells and second control gates for the memory cells, the second memory cells located along respective second pillars, the second pillars extending through the second tiers; and a dielectric structure formed in a slit between the first tiers and the second tiers, the dielectric structure including an edge along a length of the slit and adjacent the first tiers, wherein the edge has a repeating pattern of a shape. Other embodiments, including additional apparatuses and methods, are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B, and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B, and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
first tiers located one over another, the first tiers including respective first memory cells and first control gates for the memory cells, the first memory cells located along respective first pillars, the first pillars extending through the first tiers;
second tiers located one over another, the second tiers including respective second memory cells and second control gates for the memory cells, the second memory cells located along respective second pillars, the second pillars extending through the second tiers; and
a dielectric structure formed in a slit between the first tiers and the second tiers, the dielectric structure including an edge along a length of the slit and adjacent the first tiers, wherein the edge has a repeating pattern of a shape.

2. The apparatus of claim 1, wherein the edge of the dielectric structure is a first edge, and wherein the dielectric structure includes a second edge along the length of the slit and adjacent the second tiers, and the second edge has the repeating pattern of a shape.

3. The apparatus of claim 1, wherein the shape includes a zig-zag shape.

4. The apparatus of claim 1, wherein the repeating pattern includes curved segments.

5. The apparatus of claim 1, wherein the repeating pattern includes a first segment and a second segment connected to the first segment, and an angle between the first and second segments is greater than zero and less than 180 degrees.

6. The apparatus of claim 1, wherein the first control gates include respective portions that collectively form a staircase structure, wherein the edge of the dielectric structure includes a portion adjacent the staircase structure.

7. An apparatus comprising:
tiers located one over another, the tiers including respective memory cells and control gates for the memory cells, the memory cells located along respective pillars, the pillars extending in a direction from one tier to another tier among the tiers;
conductive contacts contacting the control gates, the conductive contacts having different lengths extending in the same direction as the pillars; and
support structures adjacent the conductive contacts and electrically separated from the control gates and the conductive contacts, the support structures extending in the same direction as the conductive contacts, wherein one of the support structures has a cross-section perpendicular to lengths of the support structures, and the cross-section has a non-circular shape.

8. The apparatus of claim 7, wherein the non-circular shape is a polygon.

9. The apparatus of claim 7, wherein the non-circular shape includes a straight segment, and a curved segment connected to the straight segment.

10. The apparatus of claim 7, wherein the non-circular shape is elliptical.

11. The apparatus of claim 7, wherein the control gates include respective portions that collectively form a staircase structure, and the conductive contacts contact the control gates at a location of the staircase structure.

12. The apparatus of claim 7, wherein the support structures have the same length, and the conductive contacts have difference lengths.

13. An apparatus comprising:
a block of memory cells including levels of dielectric materials interleaved with levels of conductive materials, the levels of conductive materials forming control gates for the memory cells, the levels of conductive materials including respective portions that collectively form a staircase structure;
conductive contacts contacting the levels of conductive materials at a location of the staircase structure, the conductive contacts having different lengths extending in a direction from one level to another level among the levels of dielectric materials;
support structures adjacent the conductive contacts and electrically separated from the control gates and the conductive contacts, the support structures extending in the same direction as the conductive contacts, wherein one of the support structures a has a cross-section, and the cross-section has a non-circular shape; and
a dielectric structure formed in a slit adjacent the block of memory cells, the dielectric structure including an edge along a length of the slit and adjacent the block of memory cells, wherein the edge has a repeating pattern of a shape.

14. The apparatus of claim 13, wherein the edge of the dielectric structure is a first edge, and wherein the dielectric structure includes a second edge opposite the first edge and along the length of the slit, and the second edge has an additional repeating pattern of a shape.

15. The apparatus of claim 13, wherein the control gates include respective portions that collectively form a staircase structure, wherein the edge is adjacent the staircase structure.

16. A method comprising:
forming levels of first materials interleaved with levels of second materials;
forming memory cell strings including forming respective pillars of the memory cell strings through the levels of first materials and the levels of second materials;
forming a slit through the levels of first materials and the levels of second materials to separate the levels of first materials and the levels of second materials into a first block of memory cells and a second block of memory cells, wherein the slit includes an edge having a shape based on a repeating pattern of a shape of an edge of a reticle used during part of forming the slit;
replacing the levels of second materials with respective levels of conductive materials, wherein the levels of conductive materials form respective control gates for the memory cells; and
forming a dielectric structure in the slit.

17. The method of claim 16, wherein the repeating pattern of the shape includes a zigzag shape.

18. The method of claim 16, further comprising:
forming a staircase structure from a respective portion of the levels of conductive materials, wherein the edge of the slit is adjacent the staircase structure.

19. The method of claim 16, wherein the edge of the reticle is a first edge, and wherein the reticle includes a second edge, and the second edge includes an additional repeating pattern of a shape.

20. A method comprising:
forming levels of first materials interleaved with levels of second materials;
forming memory cell strings including forming respective pillars of the memory cell strings through the levels of first materials and the levels of second materials;
forming conductive contacts contacting the levels of conductive materials, such that the conductive contacts have lengths extending in the same direction as respective lengths of the pillars; and
forming support structures adjacent the conductive contacts and electrically separated from the conductive materials and the conductive contacts, such that the support structures extend in the same direction as respective lengths of the conductive contacts, wherein a shape of a cross-section of a support structure among the support structures is based on a non-circular shape of a region of the reticle used during part of forming the support structures.

21. The method of claim 20, wherein the shape of the region of the reticle includes one of polygon, a shape having a curved segment connected to a straight segment, and elliptical.

22. The method of claim 20, further comprising:
forming a staircase structure from a respective portion of the levels of conductive materials, wherein the conductive contacts contact the levels of conductive materials at a location of the staircase structure.
